(19) United States
(12) Patent Application Publication
(10) Pub. No.: US 2025/0151440 A1
(43) Pub. Date: May 8, 2025

(54) IMAGE SENSOR AND ELECTRONIC SYSTEM INCLUDING THE SAME

(71) Applicant: SAMSUNG ELECTRONICS CO., LTD., Suwon-si (KR)

(72) Inventor: Kooktae KIM, Suwon-si (KR)

(73) Assignee: SAMSUNG ELECTRONICS CO., LTD., Suwon-si (KR)

(21) Appl. No.: 18/751,960

(22) Filed: Jun. 24, 2024

(30) Foreign Application Priority Data
Nov. 8, 2023 (KR) 10-2023-0153933

(51) Int. Cl. H01L 27/146

(52) U.S. Cl. CPC H10F 39/807; H10F 39/011; H10F 39/182; H10F 39/199; H10F 39/8053; H10F 39/8063; H10F 39/811

(57) ABSTRACT

An image sensor includes unit pixels on a substrate and a pixel isolation structure passing through the substrate in a vertical direction, defining the unit pixels, and having a network-type planar structure. The pixel isolation structure includes a line isolation portion and a corner isolation portion, the line isolation portion linearly extending along a side of each of two adjacent ones of the unit pixels between the two adjacent unit pixels, and the corner isolation portion contacting a corner of each of two adjacent ones of the unit pixels. The pixel isolation structure includes a conductive pillar including a first conductive pillar in the line isolation portion and a second conductive pillar in the corner isolation portion, and an insulating structure surrounding the conductive pillar. The conductive pillar includes a metal pillar having a width in the vertical direction that varies.

### CROSS-REFERENCE TO RELATED APPLICATION

This application is based on and claims priority under 35 U.S.C. § 119 to Korean Patent Application No. 10-2023-0153933, filed on Nov. 8, 2023, in the Korean Intellectual Property Office, the disclosure of which being incorporated by reference herein in its entirety.

### BACKGROUND

Devices, apparatuses, and systems consistent with the present disclosure relate to an image sensor and an electronic system including the same, and more particularly, to an image sensor including a pixel isolation structure configured to isolate sensing areas from each other and an electronic system including the image sensor.

With the development of the computer industry and the communication industry, image sensors that acquire images and convert the acquired images into electrical signals have been used in various fields, such as digital cameras, camcorders, personal communication systems (PCS), game devices, security cameras, and medical micro cameras. As image sensors become highly integrated and pixel sizes are miniaturized, to implement high-sensitivity image sensors, a width of each of a plurality of pixels that are sensing areas is gradually decreasing, a height thereof is gradually increasing, and an aspect ratio of a pixel isolation structure configured to isolate the plurality of pixels from each other is also increasing. In addition, as the integration density of the image sensors increases and a size of each of the plurality of pixels is reduced, new techniques may be needed to effectively control characteristics (e.g., a dark current and white spots) in the plurality of pixels and improve sensitivity.

### SUMMARY

It is an aspect to provide an image sensor having a structure that may effectively control characteristics (e.g., a dark current and white spots) and improve sensitivity in each of a plurality of unit pixels.

It is another aspect to provide an electronic system including an image sensor having a structure that may effectively control characteristics ((e.g., a dark current and white spots) and improve sensitivity in each of a plurality of unit pixels.

According to an aspect of one or more embodiments, there is provided an image sensor comprising a plurality of unit pixels arranged on a substrate; and a pixel isolation structure passing through the substrate in a vertical direction, defining the plurality of unit pixels, and having a network-type planar structure. The pixel isolation structure comprises a line isolation portion and a corner isolation portion, the line isolation portion linearly extending along a side of each of two adjacent ones of the plurality of unit pixels between the two adjacent unit pixels, and the corner isolation portion contacting a corner of each of at least two adjacent ones of the plurality of unit pixels; a conductive pillar comprising a first conductive pillar included in the line isolation portion and a second conductive pillar included in the corner isolation portion and integrally connected to the first conductive pillar; and an insulating structure surrounding the conductive pillar in each of the line isolation portion and the corner isolation portion, the insulating structure comprising a first insulating structure included in the line isolation portion and a second insulating structure included in the corner isolation portion and integrally connected to the first insulating structure, wherein the conductive pillar comprises a metal pillar included in at least one of the line isolation portion and the corner isolation portion, and a width of the metal pillar in a lateral direction is variable in the vertical direction.

According to another aspect of one or more embodiments, there is provided an image sensor comprising a plurality of unit pixels respectively comprising a plurality of photodiodes arranged in a substrate having a frontside surface and a backside surface, the plurality of unit pixels having a two-dimensional array structure arranged in a matrix form along a plurality of row lines and a plurality of column lines; and a pixel isolation structure comprising a main device isolation film and a local device isolation film, the main device isolation film passing through the substrate from the frontside surface of the substrate to the backside surface of the substrate and defining the plurality of unit pixels, the local device isolation film passing through only a portion of the substrate from the frontside surface of the substrate in a vertical direction, and covering a partial sidewall of the main device isolation film which is adjacent to the frontside surface of the substrate. The pixel isolation structure comprises a line isolation portion and a corner isolation portion, the line isolation portion linearly extending along a side of each of two adjacent ones of the plurality of unit pixels between the two adjacent unit pixels, and the corner isolation portion being in contact with a corner of each of at least two adjacent ones of the plurality of unit pixels; a conductive pillar comprising a first conductive pillar included in the line isolation portion and a second conductive pillar included in the corner isolation portion and integrally connected to the first conductive pillar; and an insulating structure surrounding the conductive pillar in each of the line isolation portion and the corner isolation portion, the insulating structure comprising a first insulating structure included in the line isolation portion and a second insulating structure included in the corner isolation portion and integrally connected to the first insulating structure, wherein the conductive pillar comprises a metal pillar included in at least one of the line isolation portion and the corner isolation portion, and a width of the metal pillar in a lateral direction is variable in the vertical direction.

According to another aspect of one or more embodiments, there is provided an electronic system comprising at least one camera module comprising an image sensor; and a processor configured to process image data provided by the at least one camera module. The image sensor comprises a plurality of unit pixels arranged on a substrate; and a pixel isolation structure passing through the substrate in a vertical direction, defining the plurality of unit pixels, and having a network-type planar structure. The pixel isolation structure comprises a line isolation portion and a corner isolation portion, the line isolation portion linearly extending along a side of each of two adjacent ones of the plurality of unit pixels between the two adjacent unit pixels, the corner isolation portion being in contact with a corner of each of at least two adjacent ones of the plurality of unit pixels; a conductive pillar comprising a first conductive pillar included in the line isolation portion and a second conductive pillar included in the corner isolation portion and integrally connected to the first conductive pillar; and an insulating structure surrounding the conductive pillar in each of the line isolation portion and the corner isolation portion, the insulating structure comprising a first insulating structure included in the line isolation portion and a second insulating structure included in the corner isolation portion and integrally connected to the first insulating structure, wherein the conductive pillar further comprises a metal pillar included in at least one of the line isolation portion and the corner isolation portion, and a width of the metal pillar in a lateral direction is variable in the vertical direction.

### BRIEF DESCRIPTION OF THE DRAWINGS

Various embodiments will be more clearly understood from the following detailed description taken in conjunction with the accompanying drawings, in which:

FIG. 1 is an exploded perspective view of an image sensor according to some embodiments;

FIG. 2 is a block diagram showing some components of an image sensor according to some embodiments;

FIG. 3 is a cross-sectional view of a partial region of an image sensor according to some embodiments;

FIG. 4 is a plan view of a pixel isolation structure included in an image sensor according to some embodiments;

FIG. 5 is an enlarged cross-sectional view of a partial region of a second semiconductor chip included in an image sensor according to some embodiments;

FIG. 6 is an enlarged cross-sectional view of partial regions of FIG. 4;

FIGS. 7 to 15 are cross-sectional views of an image sensor according to some embodiments;

FIGS. 16A to 16M are cross-sectional views showing a process sequence of a method of manufacturing an image sensor, according to some embodiments;

FIGS. 17A to 17G are cross-sectional views showing a process sequence of a method of manufacturing an image sensor, according to some embodiments;

FIGS. 18A to 18E are cross-sectional views showing a process sequence of a method of manufacturing an image sensor, according to some embodiments;

FIGS. 19A to 19G are cross-sectional views showing a process sequence of a method of manufacturing an image sensor, according to some embodiments;

FIGS. 20A to 20H are cross-sectional views showing a process sequence of a method of manufacturing an image sensor, according to some embodiments;

FIG. 21A is a block diagram of an electronic system according to some embodiments; and

FIG. 21B is a detailed block diagram of a camera module included in the electronic system of FIG. 21A, according to some embodiments.

### DETAILED DESCRIPTION

Hereinafter, various embodiments will be described in detail with reference to the accompanying drawings. The same reference numerals are used to denote the same elements in the drawings, and repeated descriptions thereof will be omitted.

It will be understood that, although the terms “first”, “second”, etc. may be used herein to describe various elements, these elements should not be limited by these terms. These terms are only used to distinguish one element from another. Unless otherwise defined, a “first” element may be termed a “second” element. For example, a “first” insulating pattern could be termed a “second” insulating pattern, and, similarly, a “second” insulating pattern could be termed a “first” insulating pattern, without departing from the scope of various embodiments described below. Each of the first insulating pattern and the second insulating pattern may be an insulating pattern, but in an embodiment, the first insulating pattern and the second insulating pattern may not be the same insulating patterns.

As used in this specification, the phrase “at least one of A and B” or “at least one of A or B” includes within its scope “only A”, “only B”, and “both A and B.”

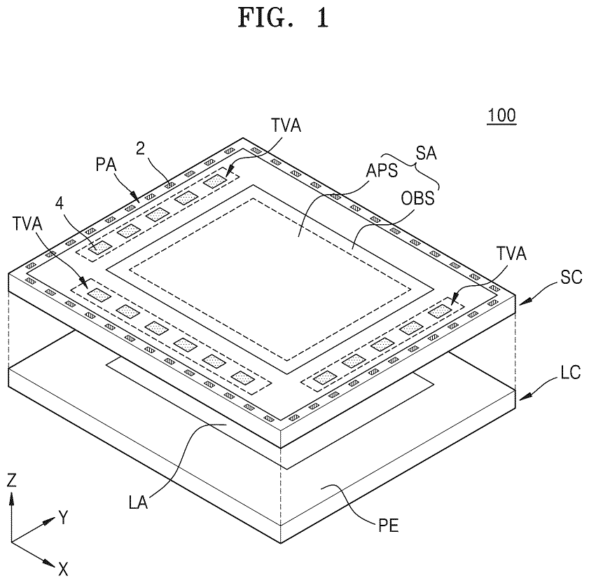

FIG. 1 is an exploded perspective view of an image sensor 100 according to some embodiments.

Referring to FIG. 1, the image sensor 100 may include a first semiconductor chip LC and a second semiconductor chip SC, which overlap each other in a vertical direction (a Z direction). The first semiconductor chip LC may be a logic chip, and the second semiconductor chip SC may be a sensor chip.

The first semiconductor chip LC may include a logic area LA including logic devices and a peripheral circuit area PE including peripheral circuits. The logic area LA may be surrounded by the peripheral circuit area PE.

The second semiconductor chip SC may be stacked on the first semiconductor chip LC and overlap the first semiconductor chip LC in the vertical direction (Z direction). The second semiconductor chip SC may include a sensor array area SA, a pad area PA surrounding the sensor array area SA, and a plurality of through via areas TVA between the sensor array area SA and the pad area PA. In the second semiconductor chip SC, the plurality of through via areas TVA and the pad area PA may constitute a peripheral circuit area of the second semiconductor chip SC.

In the second semiconductor chip SC, the sensor array area SA may include an active pixel sensor area APS and an optical black sensor area OBS. The active pixel sensor area APS may include an active pixel configured to generate active signals corresponding to the wavelengths of external light. The optical black sensor area OBS may include an optical black pixel configured to generate optical black signals by blocking external light. A dummy pixel sensor may be provided at an edge portion of the active pixel sensor area APS, which is adjacent to the optical black sensor area OBS.

A plurality of pads 2 may be in the pad area PA of the second semiconductor chip SC. In some embodiments, the plurality of pads 2 may transmit and receive electrical signals to and from an external device. In some embodiments, the plurality of pads 2 may transmit driving power (e.g., an external power supply voltage or a ground voltage) to internal circuits of the second semiconductor chip SC.

The plurality of through via areas TVA formed in the second semiconductor chip SC may include a plurality of through vias 4. Some of the through vias 4 may be connected to unit pixels in the sensor array area SA through wirings included in the second semiconductor chip SC. Some others of the through vias 4 may connect wirings included in the first semiconductor chip LC to the wirings included in the second semiconductor chip SC. Still some others of the through vias 4 may connect the wirings included in the first semiconductor chip LC to logic devices of the logic area LA included in the second semiconductor chip SC.

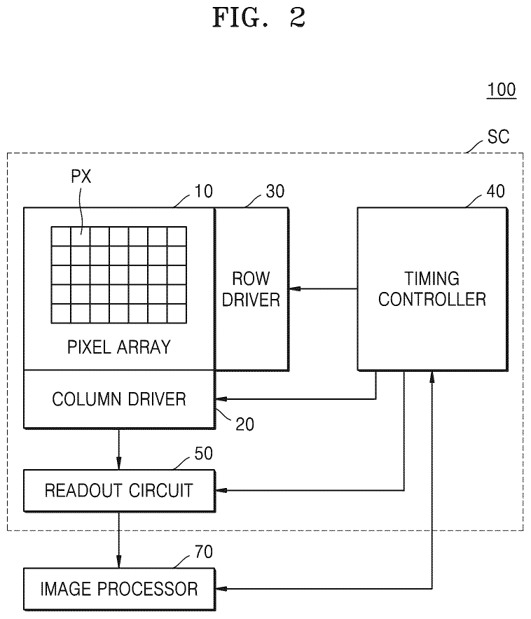

FIG. 2 is a block diagram of some components of the image sensor 100 shown in FIG. 1, according to some embodiments.

Referring to FIGS. 1 and 2, the image sensor 100 may include a pixel array located in the sensor array area SA and circuits configured to control the pixel array 10. In some embodiments, the circuits configured to control the pixel array 10 may include a column driver 20, a row driver 30, a timing controller 40, and a readout circuit 50.

The image sensor 100 may operate in response to a control command received from an image processor 70. The image sensor 100 may convert light transmitted from an external object into an electrical signal and output the electrical signal to the image processor 70. The image sensor 100 may be a complementary metal-oxide-semiconductor (CMOS) image sensor.

The pixel array 10 may include a plurality of unit pixels PX having a two-dimensional (2D) array structure arranged in a matrix form along a plurality of row lines and a plurality of column lines. As used herein, the term ‘unit pixel’ may also be simply referred to as a pixel.

Each of the plurality of unit pixels PX may include a photodiode. The photodiode may generate electric charges in response to light received from the object. The image sensor 100 may perform an autofocus function by using a phase difference between pixel signals generated from a plurality of photodiodes included in the plurality of unit pixels PX. Each of the unit pixels PX may include a pixel circuit configured to generate a pixel signal from the electric charges generated by the photodiode.

In some embodiments, the image sensor 100 may include an image sensor capable of operating as a global shutter. For example, during operations of the image sensor 100, all the unit pixels included in the pixel array 10 may be simultaneously exposed to an optical signal provided from the outside, and thus, electric charges may be simultaneously stored in the plurality of unit pixels PX. In some embodiments, pixel signals generated due to the electric charges stored in each of the plurality of unit pixels PX may be sequentially output from each row.

The column driver 20 may include a correlated double sampler (CDS) and an analog-digital converter (ADC). The CDS may be connected, through column lines, to a unit pixel PX included in a row selected by a row selection signal supplied by the row driver 30 and perform correlated double sampling to detect a reset voltage and a pixel voltage. The ADC may convert the reset voltage and the pixel voltage each detected by the CDS into digital signals and transmit the digital signals to the readout circuit 50.

The readout circuit 50 may include a latch or a buffer circuit, which may temporarily store the digital signal, and an amplification circuit. The readout circuit 50 may generate image data by temporarily storing or amplifying the digital signal received from the column driver 20. The operation timing of the column driver 20, the row driver 30, and the readout circuit 50 may be determined by the timing controller 40, and the timing controller 40 may operate based on a control command transmitted from the image processor 70.

The image processor 70 may signal-process image data output from the readout circuit 50 and output the signal-processed image data to a display device or store the signal-processed image data in a storage device, such as a memory. In an embodiment, when the image sensor 100 is mounted on an autonomous vehicle, the image processor 70 may signal-process image data and transmit the signal-processed image data to a main controller that controls the autonomous vehicle.

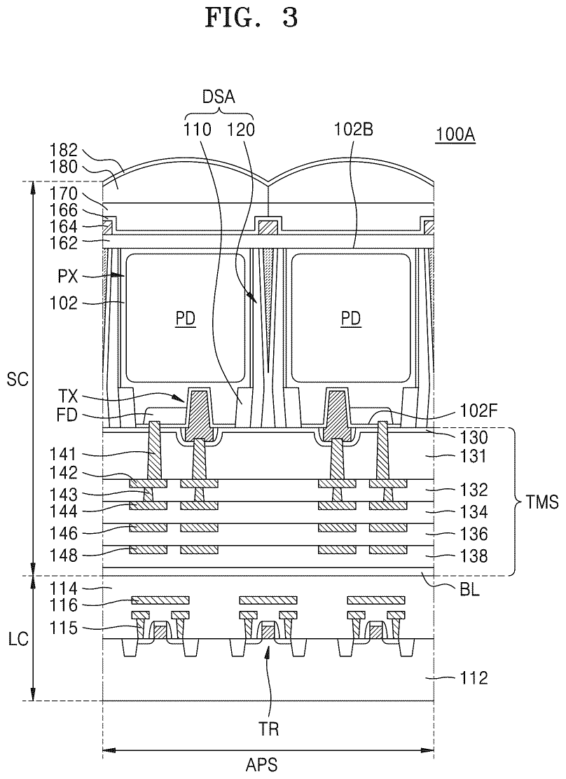

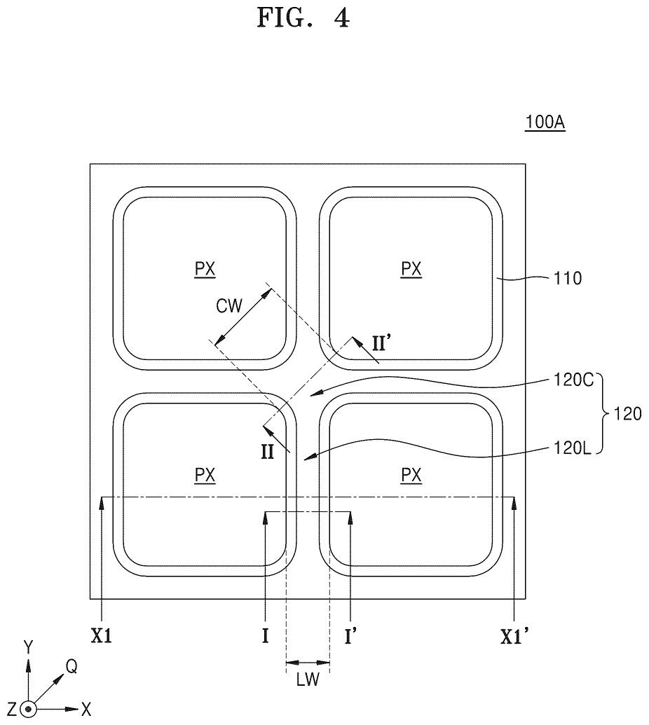

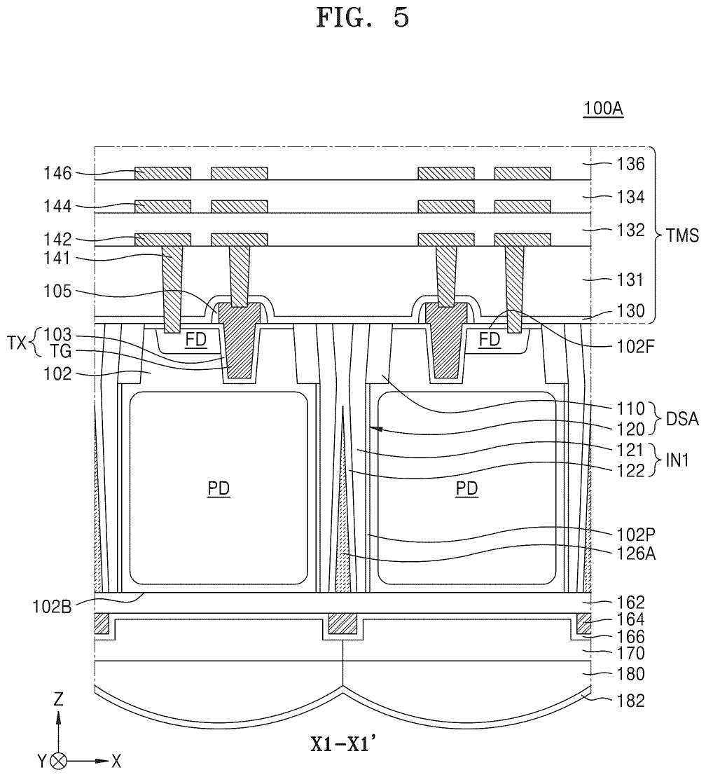

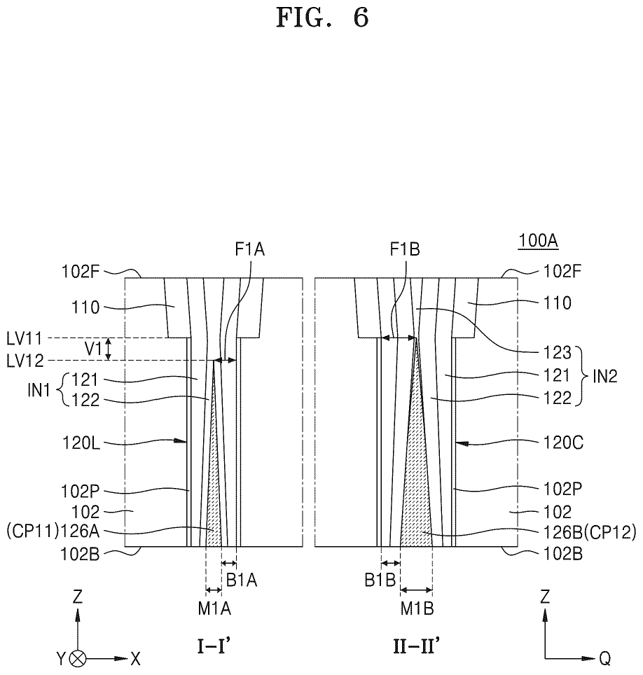

FIG. 3 is a cross-sectional view of a partial region of an image sensor 100A according to some embodiments. FIG. 3 illustrates some components of the active pixel sensor area APS of the sensor array area SA, which may be in the second semiconductor chip SC of the image sensor 100 shown in FIG. 1, and some components of a portion of a first semiconductor chip LC, which overlaps the active pixel sensor area APS in a vertical direction (Z direction). FIG. 4 is a plan view of a pixel isolation structure DSA defining each of a plurality of unit pixels PX arranged on a substrate 102 in the image sensor 100A, according to some embodiments. FIG. 5 is an enlarged cross-sectional view of a partial region of the second semiconductor chip SC of FIG. 3. FIG. 5 illustrates a cross-sectional configuration of some components in a portion corresponding to a cross-section taken along line X1-X1′ of FIG. 4. FIG. 6 is an enlarged cross-sectional view of partial regions of FIG. 4. FIG. 6 illustrates some components in cross-sections taken along lines I-I′ and II-II′ of FIG. 4. Exemplary structures of the image sensor 100A described with reference to FIGS. 3 to 6 may form a portion of the image sensor 100 shown in FIGS. 1 and 2.

Referring to FIGS. 3 to 6, in the image sensor 100A, the first semiconductor chip LC and the second semiconductor chip SC may be bonded to each other by using a bonding layer BL. The plurality of unit pixels PX configured to generate active signals corresponding to the wavelengths of external light may be in an active pixel sensor area APS of the second semiconductor chip SC.

The image sensor 100A may include a substrate 102. The substrate 102 may include a semiconductor layer. In some embodiments, the substrate 102 may include a semiconductor layer doped with P-type impurities. For example, the substrate 102 may include a semiconductor layer, which includes silicon (Si), germanium (Ge), silicon germanium (SiGe), a Group II-VI compound semiconductor, a Group III-V compound semiconductor, or a combination thereof. In some embodiments, the substrate 102 may include a P-type epitaxial semiconductor layer, which is epitaxially grown from a P-type bulk silicon substrate. The substrate 102 may have a frontside surface 102F and a backside surface 102B, which are opposite to each other.

Each of the plurality of unit pixels PX may include a photodiode PD, a floating diffusion region FD, and a transfer transistor TX. The photodiode PD and the floating diffusion region FD may be in the substrate 102. The photodiode PD may generate electric charges in proportion to the amount of light incident from the outside. The generated electric charges may be accumulated in the photodiode PD, and the electric charges accumulated in the photodiode PD may be transmitted to the floating diffusion region FD. The electric charges transmitted to the floating diffusion region FD may be applied to a source follower gate of the unit pixel PX. One end of the transfer transistor TX may be connected to the photodiode PD, and another end of the transfer transistor TX may be connected to the floating diffusion region FD. The transfer transistor TX may transmit the electric charges generated by the photodiode PD to the floating diffusion region FD.

As shown in FIG. 5, the transfer transistor TX may include a transfer gate TG and a gate insulating film 103. Sidewalls of the transfer gate TG may be covered by insulating spacers 105. The transfer gate TG may include a portion buried in the substrate 102. The gate insulating film 103 may be between the transfer gate TG and the substrate 102.

As shown in FIGS. 4 and 5, the pixel isolation structure DSA may include a local device isolation film 110 and a main device isolation film 120. The main device isolation film 120 may pass through the substrate 102 from the frontside surface 102F of the substrate 102 to the backside surface 102B of the substrate in a vertical direction (Z direction) to define the plurality of unit pixels PX. The local device isolation film 110 may pass through only a portion of the substrate 102 from the frontside surface 102F of the substrate 102 in the vertical direction (Z direction) and cover a partial sidewall of the main device isolation film 120, which covers the frontside surface 102F of the substrate 102. As used herein, the vertical direction (Z direction) may refer to a direction perpendicular to the backside surface 102B of the substrate 102. In some embodiments, the local device isolation film 110 may include a silicon oxide film.

As shown in FIG. 4, in the image sensor 100A, the pixel isolation structure DSA may have a network-type planar structure. The main device isolation film 120 of the pixel isolation structure DSA may include a line isolation portion 120L and a corner isolation portion 120C. The line isolation portion 120L may linearly extend along a side of each of two adjacent ones of the unit pixels PX between the two adjacent unit pixels PX. The corner isolation portion 120C may be in contact with a corner of each of at least two (e.g., four) adjacent ones of the unit pixels PX. The corner isolation portion 120C may be in a portion where a plurality of line isolation portions 120L meet each other. As shown in FIG. 4, the main device isolation film 120 of the pixel isolation structure DSA may have a network-type planar structure.

The line isolation portion 120L may have a first width LW in a direction (e.g., an X direction or a Y direction of FIG. 4) in which two unit pixels PX, which face each other with the line isolation portion 120L therebetween, face each other. Between two unit pixels PX, which face each other in a diagonal direction (e.g., a Q direction in FIG. 4) with the corner isolation portion 120C therebetween, the corner isolation portion 120C may have a second width CW in the diagonal direction. The second width CW may be greater than the first width LW.

As shown in FIG. 6, the pixel isolation structure DSA may include a conductive pillar CP11 and CP12. The conductive pillar CP11 and CP12 may include a first conductive pillar CP11 included in the line isolation portion 120L and a second conductive pillar CP12 included in the corner isolation portion 120C. The first conductive pillar CP11 and the second conductive pillar CP12 may be integrally connected to each other and have a network-type planar structure similar to a planar structure of the main device isolation film 120 shown in FIG. 4.

The first and second conductive pillars CP11 and CP12 included in the main device isolation film 120 may include a metal pillar 126A and 126B. The metal pillar 126A and 126B may include a first metal pillar 126A included in the line isolation portion 120L and a second metal pillar 126B included in the corner isolation portion 120C. The first metal pillar 126A and the second metal pillar 126B may be integrally connected to each other and have a network-type planar structure similar to a planar structure of the main device isolation film 120 shown in FIG. 4.

A width of each of the first metal pillar 126A and the second metal pillar 126B in a lateral direction (or X direction of FIG. 6) may be variable in the vertical direction (Z direction). For example, in the pixel isolation structure DSA, each of the first metal pillar 126A and the second metal pillar 126B may have a tapered cross-sectional shape with a width in the lateral direction (or X direction in FIG. 6) gradually increasing from the frontside surface 102F of the substrate 102 toward the backside surface 102B of the substrate 102. Accordingly, each of the first metal pillar 126A and the second metal pillar 126B may include a metallic tapered surface that faces the photodiode PD and is inclined with respect to the backside surface 102B of the substrate 102.

In the lateral direction (e.g., X direction of FIG. 6), a width MIA of the first metal pillar 126A included in the line isolation portion 120L may be less than a width M1B of the second metal pillar 126B included in the corner isolation portion 120C. For example, the width MIA of the first metal pillar 126A at the backside surface 102B may be less than the width M1B of the second metal pillar 126B at the backside surface 102B. In other words, a maximum width of the first metal pillar 126A may be less than a maximum width of the second metal pillar 126B.

In some embodiments, each of the first metal pillar 126A and the second metal pillar 126B may include a reflective metal. For example, each of the first metal pillar 126A and the second metal pillar 126B may include a reflective metal, which includes aluminum (Al), tungsten (W), copper (Cu), titanium (Ti), silver (Ag), cobalt (Co), platinum (Pt), gold (Au), chromium (Cr), nickel (Ni), molybdenum (Mo), iron (Fe), magnesium (Mg), iridium (Ir), palladium (Pd), ruthenium (Ru), or a combination thereof, without being limited thereto. In some embodiments, each of the first metal pillar 126A and the second metal pillar 126B may include a metal plug including the reflective metal described above and a conductive metal nitride film surrounding the metal plug. The conductive metal nitride film may include titanium nitride (TiN), without being limited thereto. In some embodiments, each of the first metal pillar 126A and the second metal pillar 126B may reflect light, which is incident on the pixel isolation structure DSA, toward the inside of the unit pixel PX adjacent thereto, and thus, a light gathering effect may improve in the unit pixel PX, and the sensitivity of the image sensor 100A may increase.

In some embodiments, each of the first metal pillar 126A and the second metal pillar 126B may be used as a path through which a negative bias is applied to the pixel isolation structure DSA to prevent a dark current from being generated in the unit pixel PX. Because the first metal pillar 126A and the second metal pillar 126B are connected to each other and have a network-type planar structure, a negative bias may be easily applied to the entire pixel isolation structure DSA of the image sensor 100A through the first metal pillar 126A and the second metal pillar 126B.

A first vertical level LV11 of a portion of the local device isolation film 110 of the pixel isolation structure DSA, which is closest to the backside surface 102B of the substrate 102, may be closer to the frontside surface 102F of the substrate 102 than a second vertical level LV12 of a portion of the first metal pillar 126A, which is closest to the frontside surface 102F of the substrate 102, in the line isolation portion 120L of the main device isolation film 120. A vertical distance V1 between the first vertical level LV11 and the second vertical level LV12 may be greater than 0. In some embodiments, the local device isolation film 110 may include a silicon oxide film, without being limited thereto.

The line isolation portion 120L and the corner isolation portion 120C of the main device isolation film 120 may respectively include an insulating structure IN1 and IN2 surrounding the first and second conductive pillars CP11 and CP12. The insulating structure IN1 and IN2 may include a first insulating structure IN1 included in the line isolation portion 120L and a second insulating structure IN2 included in the corner isolation portion 120C. The first insulating structure IN1 may be integrally connected to the second insulating structure IN2. In an embodiment, the first insulating structure IN1 may surround the first conductive pillar CP11 and the second insulating structure IN2 may surround the second conductive pillar CP12.

Each of the first insulating structure IN1 and the second insulating structure IN2 may have a multilayered structure including a plurality of insulating films, which have respectively different thicknesses in the lateral direction (e.g., X direction in FIG. 6). For example, each of the first insulating structure IN1 and the second insulating structure IN2 may include a first insulating pattern 121 and a second insulating pattern 122, which are sequentially stacked toward the metal pillar 126A or 126B from the outside of the main device isolation film 120. In an embodiment, the second insulating structure IN2 included in the corner isolation portion 120C may further include a third insulating pattern 123 that is at the center of the corner isolation portion 120C between both sidewalls of the corner isolation portion 120C, which are covered by the local device isolation film 110. In an embodiment, the first insulating structure IN1 included in the line isolation portion 120L may not include the third insulating pattern 123. The third insulating pattern 123 may include a silicon oxide film, without being limited thereto.

The second insulating pattern 122 may be in contact with the first metal pillar 126A in the line isolation portion 120L, and the second insulating pattern 122 may be in contact with the second metal pillar 126B in the corner isolation portion 120C. In each of the first insulating structure IN1 and the second insulating structure IN2, thicknesses of the first insulating pattern 121 and the second insulating pattern 122 may be variously selected. For instance, in an embodiment, a thickness of the first insulating pattern 121 may be less than a thickness of the second insulating pattern 122 in the lateral direction (e.g., X direction in FIG. 6), without being limited thereto. In some embodiments, each of the first insulating pattern 121 and the second insulating pattern 122 may include a silicon oxide film, borosilicate glass (BSG), phosphosilicate glass (PSG), borophosphosilicate glass (BPSG), plasma-enhanced tetraethyl orthosilicate (PE-TEOS), fluoride silicate glass (FSG), carbon-doped silicon oxide (CDO), organosilicate glass (OSG), or a combination thereof, without being limited thereto. For example, each of the first insulating pattern 121 and the second insulating pattern 122 may include a silicon oxide film.

In each of the line isolation portion 120L and the corner isolation portion 120C included in the main device isolation film 120 of the pixel isolation structure DSA, each of the first and second insulating structures IN1 and IN2 may have a shape with a width in the lateral direction (or X direction in FIG. 6) gradually increasing from the backside surface 102B of the substrate 102 toward the frontside surface 102F of the substrate 102. In the lateral direction (e.g., X direction in FIG. 6), of the first insulating structure IN1 included in the line isolation portion 120L, a width F1A of a portion that is adjacent to the frontside surface 102F of the substrate 102 and covers the first metal pillar 126A may be greater than a width B1A of a portion that is adjacent to the backside surface 102B of the substrate 102 and covers the first metal pillar 126A. In the lateral direction (e.g., X direction in FIG. 6), of the second insulating structure IN2 included in the corner isolation portion 120C, a width F1B of a portion that is adjacent to the frontside surface 102F of the substrate 102 and covers the second metal pillar 126B may be greater than a width B1B of a portion that is adjacent to the backside surface 102B of the substrate 102 and covers the second metal pillar 126B.

A doped isolation liner 102P may be between the substrate 102 and the main device isolation film 120. In the line isolation portion 120L and the corner isolation portion 120C, the first insulating pattern 121 may be in contact with the doped isolation liner 102P. The doped isolation liner 102P may include a silicon region doped with P+-type impurities. For example, the doped isolation liner 102P may include a silicon region doped with boron (B) ions, without being limited thereto. The doped isolation liner 102P may improve the quality of the image sensor 100A by reducing a dark current in the unit pixel PX. The doped isolation liner 102P may reduce a dark current generated by electron-hole pairs that occur due to surface defects between the main device isolation film 120 and the doped isolation liner 102P.

As shown in FIG. 5, an etch stop film 130 covering the transfer gate TG may be on the frontside surface 102F of the substrate 102. The etch stop film 130 may conformally cover the transfer gate TG, the insulating spacers 105, the floating diffusion region FD, and the pixel isolation structure DSA. The etch stop film 130 may include silicon nitride, silicon oxynitride, or a combination thereof, without being limited thereto.

As shown in FIG. 3, the image sensor 100A may include a backside insulating film 162 covering the backside surface 102B of the substrate 102 and a plurality of grid patterns 164, a plurality of color filters 170, and a plurality of microlenses 180, which are on the backside insulating film 162.

In some embodiments, the backside insulating film 162 may include a silicon oxide film, a silicon nitride film, a silicon oxynitride film, an aluminum oxide film, a hafnium oxide film, or a combination thereof, without being limited thereto. The backside insulating film 162 may serve as an anti-reflective film. The backside insulating film 162 may improve a light reception rate of the photodiode PD by preventing reflection of light incident on the substrate 102 from the outside. The backside insulating film 162 may have a flattened surface. The plurality of color filters 170 and the plurality of microlenses 180 may be arranged on the flattened surface of the backside insulating film 162, and thus, respective heights of the plurality of color filters 170 and the plurality of microlenses 180 may be made uniform.

The plurality of color filters 170 may be arranged to correspond to the unit pixels PX on the backside insulating film 162. The plurality of color filters 170 may include various color filters depending on the unit pixel PX. In some embodiments, the plurality of color filters 170 may be arranged in a Bayer pattern including a red color filter, a green color filter, and a blue color filter. In some embodiments, the plurality of color filters 170 may include a yellow filter, a magenta filter, and a cyan filter and may further include a white filter.

The grid pattern 164 may include a material having a lower refractive index than silicon (Si). In some embodiments, the grid pattern 164 may include a silicon oxide film, aluminum oxide film, a tantalum oxide film, or a combination thereof, without being limited thereto.

A first protective film 166 may be between the backside insulating film 162 and the plurality of color filters 170 and between the plurality of grid patterns 164 and the plurality of color filters 170. The first protective film 166 may conformally cover a top surface of the backside insulating film 150 and a side surface and a top surface of the grid pattern 164. The first protective film 166 may prevent the backside insulating film 162 and the grid pattern 164 from being damaged. The first protective film 166 may include an aluminum oxide film, without being limited thereto.

A second protective film 182 may be formed on the microlens 180. The second protective film 182 may conformally cover a surface of the microlens 180. The second protective film 182 may protect the microlens 180 from external shocks and improve light-condensing capability of the microlens 180. In some embodiments, the second protective film 182 may include a silicon oxide film, a titanium oxide film, a zirconium oxide film, a hafnium oxide film, or a combination thereof, without being limited thereto.

A wiring structure TMS may be on the frontside surface 122F of the substrate 102. The wiring structure TMS may include a plurality of interlayer insulating films (e.g., 131, 132, 134, 136, and 138) covering a plurality of transfer transistors TX, a plurality of via contacts (e.g., 141 and 143) and a plurality of wiring layers (e.g., 142, 144, 146, and 148), which are covered by the interlayer insulating films 131, 132, 134, 136, and 138, and a bonding layer BL. Some of the via contacts 141 and 143 may electrically connect the floating diffusion region FD to the wiring layers 142, 144, 146, and 148. The stacked numbers and arrangements of the interlayer insulating films 131, 132, 134, 136, and 138 and the wiring layers 142, 144, 146, and 148 are not limited to those illustrated in FIG. 3 and may be variously changed and modified as needed. The wiring layers 142, 144, 146, and 148 may include conductive lines connected to a plurality of transistors, which are electrically connected to the photodiode PD. An electrical signal converted by the photodiode PD may be signal-processed through the wiring layers 142, 144, 146, and 148. In some embodiments, the interlayer insulating films 131, 132, 134, 136, and 138 may include a silicon oxide film, a silicon nitride film, a silicon oxynitride film, a low-k dielectric film having a lower dielectric constant than the silicon oxide film, or a combination thereof, without being limited thereto. In some embodiments, each of the via contacts 141 and 143 and the wiring layers 142, 144, 146, and 148 may include tungsten (W), copper (Cu), aluminum (Al), gold (Au), silver (Ag), or a combination thereof, without being limited thereto.

As shown in FIG. 3, the first semiconductor chip LC may include a logic substrate 112 and a plurality of transistors TR on the logic substrate 112. The plurality of transistors TR may constitute a logic circuit. In some embodiments, the plurality of transistors TR may constitute a circuit configured to control transistors included in the second semiconductor chip SC.

An interlayer insulating film 114 covering the plurality of transistors TR and a plurality of via contacts 115 and a plurality of wiring layers 116, which are covered by the interlayer insulating film 114, may be on the logic substrate 112. The plurality of transistors TR may be electrically connected to the plurality of wiring layers 116 through the plurality of via contacts 115. The interlayer insulating film 114 may include a silicon oxide film, a silicon nitride film, a silicon oxynitride film, a low-k dielectric film having a lower dielectric constant than the silicon oxide film, or a combination thereof, without being limited thereto. The plurality of via contacts 115 and the plurality of wiring layers 116 may each include tungsten (W), copper (Cu), aluminum (Al), gold (Au), silver (Ag), or a combination thereof, without being limited thereto.

The image sensor 100A described with reference to FIGS. 3 to 6 may include the pixel isolation structure DSA, which passes through the substrate 102 in the vertical direction (Z direction) to define the plurality of unit pixels PX and has the network-type planar structure. The pixel isolation structure DSA may include a line isolation portion 120L and a corner isolation portion 120C. The line isolation portion 120L may linearly extend along a side of each of two adjacent ones of the unit pixels PX between the two adjacent unit pixels PX. The corner isolation portion 120C may be in contact with a corner of each of at least two adjacent ones of the unit pixels PX. The pixel isolation structure DSA may include the first and second conductive pillars CP11 and CP12, which respectively constitute portions of the line isolation portion 120L and the corner isolation portion 120C and are integrally connected to each other, and the first and second insulating structures IN1 and IN2, which are respectively surrounded by the first and second conductive pillars CP11 and CP12. The first and second conductive pillars CP11 and CP12 may include a metal having a relatively high reflectance, and thus, a light gathering effect may improve in each of the plurality of unit pixels PX. The first and second conductive pillars CP11 and CP12 may be respectively and electrically connected to the first and second insulating structures IN1 and IN2 through the line isolation portion 120L and the corner isolation portion 120C, thereby forming a network structure serving as a supporter capable of preventing problems (e.g., shift, collapse, and/or deformation) of the pixel isolation structure DSA and peripheral components thereof during and/or after the manufacture of the image sensor 100A. By applying a negative bias to the pixel isolation structure DSA through the first and second conductive pillars CP11 and CP12, characteristics (e.g., a dark current and white spots) of each of all the unit pixels PX defined by the pixel isolation structure DSA may be effectively controlled. Accordingly, the sensitivity and resolution of the image sensor 100A may improve.

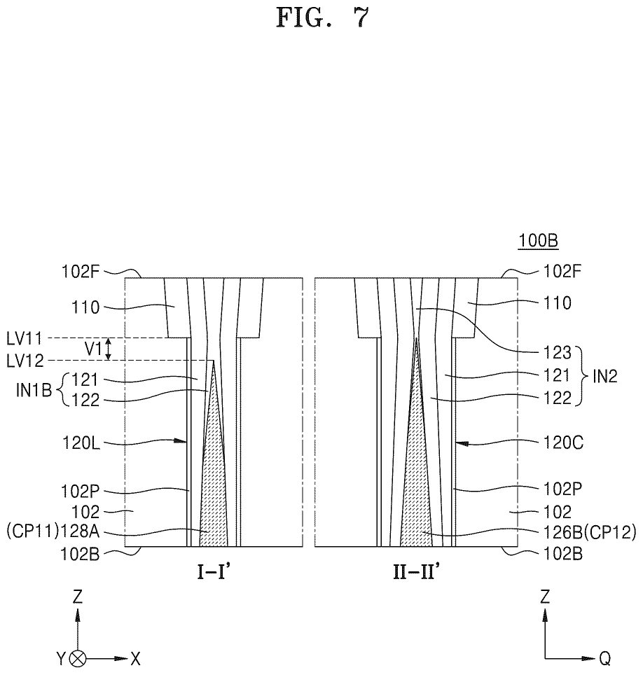

FIG. 7 is a cross-sectional view of an image sensor 100B according to some embodiments. FIG. 7 illustrates an enlarged cross-sectional configuration of portions of the image sensor 100B, which correspond to partial regions of FIG. 4. In FIG. 7, the same reference numerals are used to denote the same elements as in FIGS. 1 to 6, and detailed descriptions thereof are omitted for conciseness.

Referring to FIG. 7, the image sensor 100B may substantially have the same configuration as the image sensor 100A described with reference to FIGS. 3 to 6. However, in the image sensor 100B, a line isolation portion 120L of a main device isolation film 120 may include a first metal pillar 128A and a first insulating structure IN1B surrounding the first metal pillar 128A. Like the first insulating structure IN1 described with reference to FIGS. 3 to 6, the first insulating structure IN1B may include a first insulating pattern 121 and a second insulating pattern 122. However, each of the first insulating pattern 121 and the second insulating pattern 122 may be in contact with the first metal pillar 128A. The first metal pillar 128A may substantially have the same configuration as the first metal pillar 126A described with reference to FIG. 6. However, in the lateral direction (or X direction in FIG. 7), a maximum width of the first metal pillar 128A may be greater than a maximum width of the second insulating pattern 122 included in the first insulating structure IN1B.

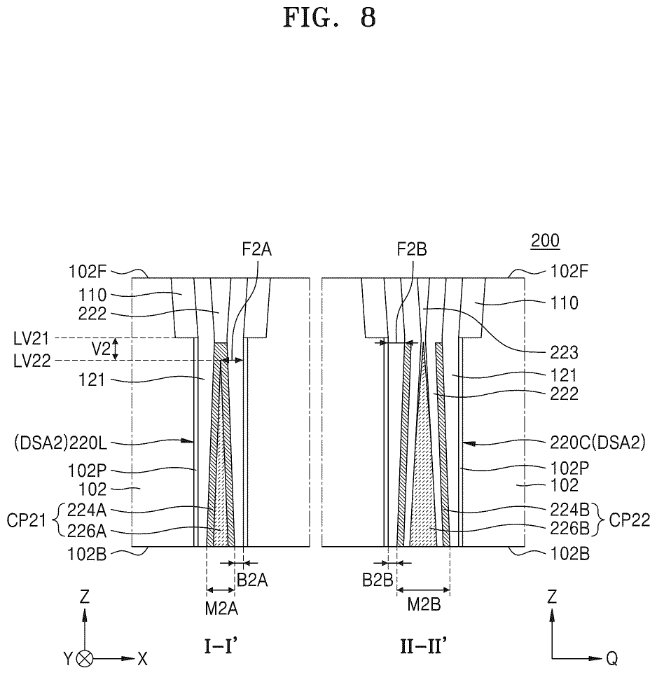

FIGS. 8 to 15 are respectively cross-sectional views of image sensors 200, 300A, 300B, 400A, 400B, 400C, 500A, and 500B according to some embodiments. FIGS. 8 to 15 illustrate enlarged cross-sectional configurations of portions of the image sensors 200, 300A, 300B, 400A, 400B, 400C, 500A, and 500B, which correspond to partial regions of FIG. 4. In FIGS. 8 to 15, the same reference numerals are used to denote the same elements as in FIGS. 1 to 6, and detailed descriptions thereof are omitted for conciseness.

Referring to FIG. 8, the image sensor 200 may substantially have the same configuration as the image sensor 100A described with reference to FIGS. 3 to 6. However, a pixel isolation structure DSA2 of the image sensor 200 may include a conductive pillar CP21 and CP22. The conductive pillar CP21 and CP22 may include a first conductive pillar CP21 included in a line isolation portion 220L and a second conductive pillar CP22 included in the corner isolation portion 220C. The first conductive pillar CP21 and the second conductive pillar CP22 may be integrally connected to each other to form a network-type planar structure.

The first conductive pillar CP21 included in the line isolation portion 220L may include a first metal pillar 226A and a first doped polysilicon pattern 224A in contact with the first metal pillar 226A. The second conductive pillar CP22 included in the corner isolation portion 22C may include a second metal pillar 226B and a second doped polysilicon pattern 224B spaced apart from the second metal pillar 226B. The first doped polysilicon pattern 224A and the second doped polysilicon pattern 224B may be connected to each other. Therefore, even when the second metal pillar 226B is spaced apart from the second doped polysilicon pattern 224B in the corner isolation portion 220C, the second conductive pillar CP22 including the second metal pillar 226B and the second doped polysilicon pattern 224B may be electrically connectable to the first conductive pillar CP21 through the first doped polysilicon pattern 224A and the second doped polysilicon pattern 224B.

In some embodiments, each of the first doped polysilicon pattern 224A and the second doped polysilicon pattern 224B may include polysilicon doped with P-type impurities or polysilicon doped with N-type impurities. For instance, each of the first doped polysilicon pattern 224A and the second doped polysilicon pattern 224B may include polysilicon doped with boron (B) or phosphorus (P), without being limited thereto.

In a lateral direction (e.g., X direction in FIG. 8), a width M2A of the first conductive pillar CP21 included in the line isolation portion 220L may be less than a width M2B of the second conductive pillar CP22 included in the corner isolation portion 220C. The width M2A of the first conductive pillar CP21 may be determined by a width of the first doped polysilicon pattern 224A in the lateral direction, and the width M2B of the second conductive pillar CP22 may be determined by a width of the second doped polysilicon pattern 224B in the lateral direction. A width of each of the first doped polysilicon pattern 224A and the second doped polysilicon pattern 224B in the lateral direction may increase away from a local device isolation film 110 in the vertical direction (Z direction). In an embodiment, the width M2A of the first conductive pillar CP21 at the backside surface 102B may be less than the width M2B of the second conductive pillar CP22 at the backside surface 102B. In other words, in some embodiments, a maximum width of the first conductive pillar CP21 may be less than a maximum width of the second conductive pillar CP22.

The first metal pillar 226A and the second metal pillar 226B may substantially and respectively have the same configurations as the first metal pillar 126A and the second metal pillar 126B described with reference to FIGS. 3 to 6. The first metal pillar 226A and the second metal pillar 226B may be integrally connected to each other to form a network-type planar structure. A width of each of the first metal pillar 226A and the second metal pillar 226B in the lateral direction (or X direction in FIG. 8) may be variable in the vertical direction (Z direction). For example, each of the first metal pillar 226A and the second metal pillar 226B may have a tapered cross-sectional shape with a width in the lateral direction (or X direction in FIG. 8) gradually increasing from a frontside surface 102F of the substrate 102 toward a backside surface 102B thereof. In some embodiments, each of the first metal pillar 226A and the second metal pillar 226B may reflect light, which is incident on the pixel isolation structure DSA2, toward the inside of the unit pixel PX adjacent thereto, and thus, a light gathering effect may improve in the unit pixel PX, and the sensitivity of the image sensor 200 may increase.

In some embodiments, each of the first conductive pillar CP21 included in the line isolation portion 220L and the second conductive pillar CP22 included in the corner isolation portion 220C may be used as a path through which a negative bias is applied to the pixel isolation structure DSA2 to prevent a dark current from being generated in the unit pixel PX. Because the first conductive pillar CP21 and the second conductive pillar CP22 are connected to each other and have a network-type planar structure, a negative bias may be easily applied to the entire pixel isolation structure DSA2 of the image sensor 200 through the first conductive pillar CP21 and the second conductive pillar CP22.

A first vertical level LV21 of a portion of the local device isolation film 110 of the pixel isolation structure DSA2, which is closest to the backside surface 102B of the substrate 102, may be closer to the frontside surface 102F of the substrate 102 than a second vertical level LV22 of a portion of the first metal pillar 226A of the line isolation portion 220L, which is closest to the frontside surface 102F of the substrate 102. A vertical distance V2 between the first vertical level LV21 and the second vertical level LV22 may be greater than 0.

The line isolation portion 220L of the pixel isolation structure DSA2 may include a first insulating pattern 121 and a second insulating pattern 222. The first insulating pattern 121 may be between the doped isolation liner 102P and the first doped polysilicon pattern 224A. The second insulating pattern 222 may be at the center of the line isolation portion 220L between both sidewalls of the line isolation portion 220L, which are covered by the local device isolation film 110. In the line isolation portion 220L, the first insulating pattern 121 and the second insulating pattern 222 may constitute a first insulating structure. The corner isolation portion 220C of the pixel isolation structure DSA2 may include the first insulating pattern 121, the second insulating pattern 222, and a third insulating pattern 223. The first insulating pattern 121 may be between the doped isolation liner 102P and the second doped polysilicon pattern 224B. The second insulating pattern 222 may be between the second doped polysilicon pattern 224B and the second metal pillar 226B. The third insulating pattern 223 may be at the center of the corner isolation portion 220C between both sidewalls of the corner isolation portion 220C, which are covered by the local device isolation film 110. In the corner isolation portion 220C, the first insulating pattern 121, the second insulating pattern 222, and the third insulating pattern 223 may constitute a second insulating structure.

The first insulating structure included in the line isolation portion 220L may be integrally connected to the second insulating structure included in the corner isolation portion 220C. Each of the first doped polysilicon pattern 224A and the second doped polysilicon pattern 224B may be surrounded by the first insulating pattern 121 and be spaced apart from the local device isolation film 110 with the first insulating pattern 121 therebetween. Constituent materials of the first insulating pattern 121, the second insulating pattern 222, and the third insulating pattern 223 may substantially and respectively the same as those of the first insulating pattern 121 and the second insulating pattern 122, which are described with reference to FIGS. 3 to 6.

In each of the line isolation portion 220L and the corner isolation portion 220C of the pixel isolation structure DSA2, the first insulating pattern 121 may have a shape with a width in the lateral direction (or X direction in FIG. 8) gradually increasing from the backside surface 102B of the substrate 102 toward the frontside surface 102F thereof. In the lateral direction (e.g., X direction in FIG. 8), of the first insulating pattern 121 included in the line isolation portion 220L, a width F2A of a portion that is adjacent to the frontside surface 102F of the substrate 102 and covers the first conductive pillar CP21 may be greater than a width B2A of a portion that is adjacent to the backside surface 102B of the substrate 102 and covers the first doped polysilicon pattern 224A of the first conductive pillar CP21. In the lateral direction (e.g., X direction in FIG. 8), of the first insulating pattern 121 included in the corner isolation portion 220C, a width F2B of a portion that is adjacent to the frontside surface 102F of the substrate 102 and covers the second doped polysilicon pattern 224B of the second conductive pillar CP22 may be greater than a width B2B of a portion that is adjacent to the backside surface 102B of the substrate 102 and covers the second doped polysilicon pattern 224B of the second conductive pillar CP22.

A doped isolation liner 102P may be between the substrate 102 and the line isolation portion 220L and between the substrate 102 and the corner isolation portion 220C. In the line isolation portion 220L and the corner isolation portion 220C, the first insulating pattern 121 may be in contact with the doped isolation liner 102P.

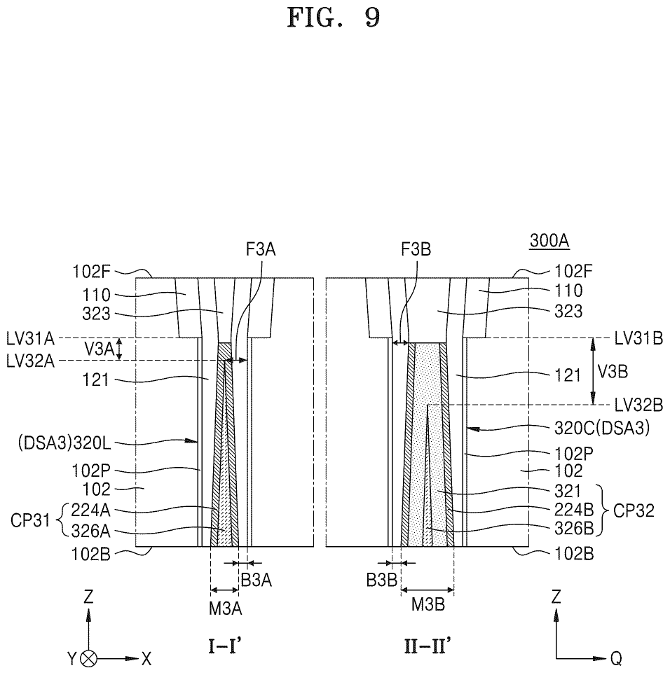

Referring to FIG. 9, the image sensor 300A may substantially have the same configuration as the image sensor 200 described with reference to FIG. 8. However, a pixel isolation structure DSA3 of the image sensor 300A may include a conductive pillar CP31 and CP32. The conductive pillar CP31 and CP32 may include a first conductive pillar CP31 included in a line isolation portion 320L and a second conductive pillar CP32 included in a corner isolation portion 320C. The first conductive pillar CP31 and the second conductive pillar CP32 may be integrally connected to each other to form a network-type planar structure.

The first conductive pillar CP31 included in the line isolation portion 320L may include a first metal pillar 326A and a first doped polysilicon pattern 224A in contact with the first metal pillar 326A. The second conductive pillar CP32 included in the corner isolation portion 320C may include a second metal pillar 326B, a second doped polysilicon pattern 224B spaced apart from the second metal pillar 326B, and an inner polysilicon pattern 321 between the second metal pillar 326B and the second doped polysilicon pattern 224B.

The first doped polysilicon pattern 224A and the second doped polysilicon pattern 224B may be connected to each other. The inner polysilicon pattern 321 may include doped polysilicon, undoped polysilicon, or a combination thereof. The doped polysilicon may include a P-type dopant or an N-type dopant. In the corner isolation portion 320C, the inner polysilicon pattern 321 may be surrounded by the second doped polysilicon pattern 224B and be in contact with each of the second doped polysilicon pattern 224B and the second metal pillar 326B. Accordingly, the second conductive pillar CP32 may be electrically connectable to the first conductive pillar CP31 through the first doped polysilicon pattern 224A and the second doped polysilicon pattern 224B.

In a lateral direction (e.g., an X direction of FIG. 9), a width M3A of the first conductive pillar CP31 included in the line isolation portion 320L may be less than a width M3B of the second conductive pillar CP32 included in the corner isolation portion 320C. The width M3A of the first conductive pillar CP31 may be determined by a width of the first doped polysilicon pattern 224A in the lateral direction, and the width M3B of the second conductive pillar CP32 may be determined by a width of the second doped polysilicon pattern 224B in the lateral direction. In each of the line isolation portion 320L and the corner isolation portion 320C, a width of each of the first doped polysilicon pattern 224A and the second doped polysilicon pattern 224B in the lateral direction may increase away from the local device isolation film 110 in a vertical direction (Z direction). In an embodiment, the width M3A of the first conductive pillar CP31 at the backside surface 102B may be less than the width M3B of the second conductive pillar CP32 at the backside surface 102B. In other words, in some embodiments, a maximum width of the first conductive pillar CP31 may be less than a maximum width of the second conductive pillar CP32.

The first metal pillar 326A and the second metal pillar 326B may substantially and respectively have the same configurations as the first metal pillar 126A and the second metal pillar 126B described with reference to FIGS. 3 to 6. The first metal pillar 326A and the second metal pillar 326B may be integrally connected to each other to form a network-type planar structure. A width of each of the first metal pillar 326A and the second metal pillar 326B in the lateral direction (X direction in FIG. 9) may be variable in the vertical direction (Z direction). For example, each of the first metal pillar 326A and the second metal pillar 326B may have a tapered cross-sectional shape with a width in the lateral direction (or X direction in FIG. 9) gradually increasing from a frontside surface 102F of a substrate 102 toward a backside surface 102B thereof. In some embodiments, each of the first metal pillar 326A and the second metal pillar 326B may reflect light, which is incident on the pixel isolation structure DSA3, toward the inside of the unit pixel PX adjacent thereto, and thus, a light gathering effect may improve in the unit pixel PX, and the sensitivity of the image sensor 300A may increase.

In some embodiments, each of the first conductive pillar CP31 included in the line isolation portion 320L and the second conductive pillar CP32 included in the corner isolation portion 320C may be used as a path through which a negative bias is applied to the pixel isolation structure DSA3 to prevent a dark current from being generated in the unit pixel PX. Because the first conductive pillar CP31 and the second conductive pillar CP32 are connected to each other and have a network-type planar structure, a negative bias may be easily applied to the entire pixel isolation structure DSA3 of the image sensor 300A through the first conductive pillar CP31 and the second conductive pillar CP32.

The first metal pillar 326A included in the line isolation portion 320L of the pixel isolation structure DSA3 may be closer to the frontside surface 102F of the substrate 102 than the second metal pillar 326B included in the corner isolation portion 320C of the pixel isolation structure DSA3. In the line isolation portion 320L, a first vertical level LV31A of a portion of the local device isolation film 110 of the pixel isolation structure DSA3, which is closest to the backside surface 102B of the substrate 102, may be closer to the frontside surface 102F of the substrate 102 than a second vertical level LV32A of a portion of the first metal pillar 326A of the line isolation portion 320L, which is closest to the frontside surface 102F of the substrate 102. A vertical distance V3A between the first vertical level LV31A and the second vertical level LV32A may be greater than 0. In the corner isolation portion 320C, a first vertical level LV31B of a portion of the local device isolation film 110 of the pixel isolation structure DSA3, which is closest to the backside surface 102B of the substrate 102, may be closer to the frontside surface 102F of the substrate 102 than a second vertical level LV32B of the second metal pillar 326B of the corner isolation portion 320C, which is closest to the frontside surface 102F of the substrate 102. A vertical distance V3B between the first vertical level LV31B and the second vertical level LV32B may be greater than the vertical distance V3A in the line isolation portion 320L.

The line isolation portion 320L of the pixel isolation structure DSA3 may include a first insulating pattern 121 and a second insulating pattern 323. The first insulating pattern 121 may be between a doped isolation liner 102P and the first doped polysilicon pattern 224A. The second insulating pattern 323 may be at the center of the line isolation portion 320L between both sidewalls of the line isolation portion 320L, which are covered by the local device isolation film 110. In the line isolation portion 320L, the first insulating pattern 121 and the second insulating pattern 323 may constitute a first insulating structure. The corner isolation portion 320C of the pixel isolation structure DSA3 may include the first insulating pattern 121 and the second insulating pattern 323. The first insulating pattern 121 may be between the doped isolation liner 102P and the second doped polysilicon pattern 224B. The second insulating pattern 323 may be at the center of the corner isolation portion 320C between both sidewalls of the corner isolation portion 320C, which are covered by the local device isolation film 110. In the corner isolation portion 320C, the first insulating pattern 121 and the second insulating pattern 323 may constitute a second insulating structure.

The first insulating structure included in the line isolation portion 320L may be integrally connected to the second insulating structure included in the corner isolation portion 320C. Each of the first doped polysilicon pattern 224A and the second doped polysilicon pattern 224B may be surrounded by the first insulating pattern 121 and be spaced apart from the local device isolation film 110 with the first insulating pattern 121 therebetween. A constituent material of the second insulating pattern 323 may substantially have the same as those of the first insulating pattern 121 and the second insulating pattern 122, which are described with reference to FIGS. 3 to 6.

In each of the line isolation portion 320L and the corner isolation portion 320C of the pixel isolation structure DSA3, the first insulating pattern 121 may have a shape with a width in the lateral direction (or X direction in FIG. 9) gradually increasing from the backside surface 102B of the substrate 102 toward the front surface 102A thereof. In the lateral direction (e.g., X direction in FIG. 9), of the first insulating pattern 121 included in the line isolation portion 320L, a width F3A of a portion that is adjacent to the frontside surface 102F of the substrate 102 and covers the first doped polysilicon pattern 224A of the first conductive pillar CP31 may be greater than a width B3A of a portion that is adjacent to the backside surface 102B of the substrate 102 and covers the first doped polysilicon pattern 224A of the first conductive pillar CP31. In the lateral direction (e.g., X direction in FIG. 9), of the first insulating pattern 121 included in the corner isolation portion 320C, a width F3B of a portion that is adjacent to the frontside surface 102F of the substrate 102 and covers the second doped polysilicon pattern 224B of the second conductive pillar CP32 may be greater than a width B3B of a portion that is adjacent to the backside surface 102B of the substrate 102 and covers the second doped polysilicon pattern 224B of the second conductive pillar CP32.

A doped isolation liner 102P may be between the substrate 102 and the line isolation portion 320L and between the substrate 102 and the corner isolation portion 320C. In the line isolation portion 320L and the corner isolation portion 320C, the first insulating pattern 121 may be in contact with the doped isolation liner 102P.

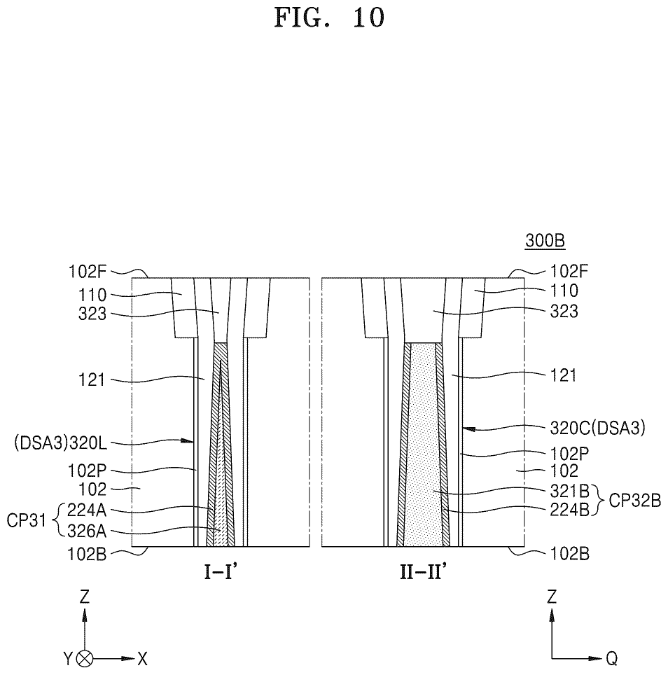

Referring to FIG. 10, the image sensor 300B may substantially have the same configuration as the image sensor 300A described with reference to FIG. 9. However, in the image sensor 300B, a second conductive pillar CP32B included in a corner isolation portion 320C of a pixel isolation structure may include an inner polysilicon pattern 321B surrounded by a second doped polysilicon pattern 224B.

The inner polysilicon pattern 321B may substantially have the same configuration as the inner polysilicon pattern 321 described with reference to FIG. 9. However, the inner polysilicon pattern 321B may be at the center of the corner isolation portion 320C. The inner polysilicon pattern 321B may include doped polysilicon, undoped polysilicon, or a combination thereof. The doped polysilicon may include a P-type dopant or an N-type dopant. The corner isolation portion 320C may not include a component corresponding to the second metal pillar 326B shown in FIG. 9. The corner isolation portion 320C may not include a metal.

Because the first doped polysilicon pattern 224A and the second doped polysilicon pattern 224B are connected to each other and the inner polysilicon pattern 321 is in contact with the second doped polysilicon pattern 224B, the second conductive pillar CP32B may be electrically connectable to the first conductive pillar CP31 through the first doped polysilicon pattern 224A and the second doped polysilicon pattern 224B.

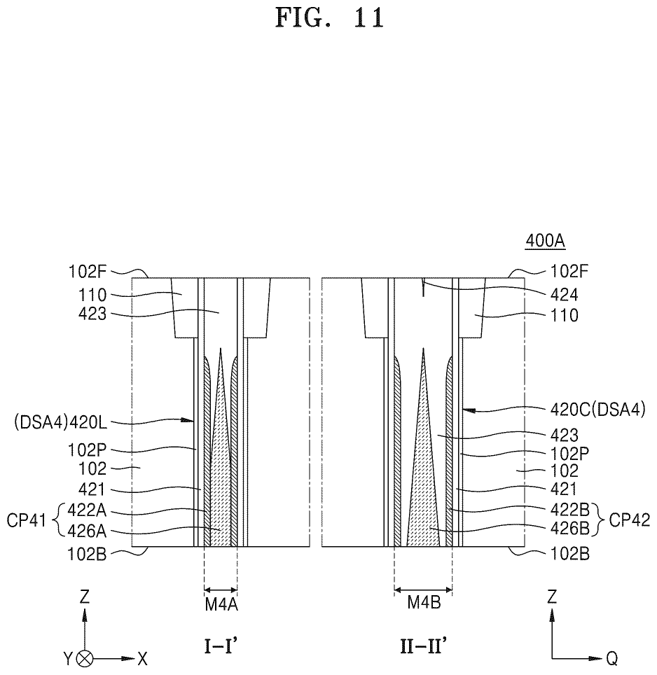

Referring to FIG. 11, the image sensor 400A may substantially have the same configuration as the image sensor 200 described with reference to FIG. 8. However, a pixel isolation structure DSA4 of the image sensor 400A may include a conductive pillar CP41 and CP42. The conductive pillar CP41 and CP42 may include a first conductive pillar CP41 included in a line isolation portion 420L and a second conductive pillar CP42 included in a corner isolation portion 420C. The first conductive pillar CP41 and the second conductive pillar CP42 may be integrally connected to each other to form a network-type planar structure.

The first conductive pillar CP41 included in the line isolation portion 420L may include a first metal pillar 426A and a first doped polysilicon pattern 422A including a portion in contact with the first metal pillar 426A. The second conductive pillar CP42 included in the corner isolation portion 420C may include a second metal pillar 426B and a second doped polysilicon pattern 422B spaced apart from the second metal pillar 426B. In the line isolation portion 420L, a first portion of the first doped polysilicon pattern 422A may be in contact with the first metal pillar 426A, and a second portion of the first doped polysilicon pattern 422A may be spaced apart from the first metal pillar 426A with a second insulating pattern 423 therebetween. In the corner isolation portion 420C, the second doped polysilicon pattern 422B may be spaced apart from the second metal pillar 426B with the second insulating pattern 423 therebetween.

The first metal pillar 426A and the second metal pillar 426B may substantially and respectively have the same configurations as the first metal pillar 126A and the second metal pillar 126B, which are described with reference to FIGS. 3 to 6. The first metal pillar 426A and the second metal pillar 426B may be integrally connected to each other to form a network-type planar structure. A width of each of the first metal pillar 426A and the second metal pillar 426B in a lateral direction (or X direction in FIG. 11) may be variable in a vertical direction (Z direction). For example, each of the first metal pillar 426A and the second metal pillar 426B may have a tapered cross-sectional shape with a width in the lateral direction (or X direction in FIG. 11) gradually increasing from a frontside surface 102F of a substrate 102 toward a backside surface 102B thereof. In some embodiments, each of the first metal pillar 426A and the second metal pillar 426B may reflect light, which is incident on the pixel isolation structure DSA4, toward the inside of the unit pixel PX adjacent thereto, and thus, a light gathering effect may improve in the unit pixel PX, and the sensitivity of the image sensor 400A may increase.

The first doped polysilicon pattern 422A and the second doped polysilicon pattern 422B may be connected to each other. Accordingly, the second conductive pillar CP42 may be electrically connectable to the first conductive pillar CP41 through the first doped polysilicon pattern 422A and the second doped polysilicon pattern 422B.

Each of the first doped polysilicon pattern 422A and the second doped polysilicon pattern 422B may include silicon doped with P+-type impurities. The P+-type impurities may include boron (B) ions. In the lateral direction (e.g., X direction of FIG. 11), a width M4A of the first conductive pillar CP41 included in the line isolation portion 420L may be less than a width M4B of the second conductive pillar CP42 included in the corner isolation portion 420C. The width M4A of the first conductive pillar CP41 may be determined by a width of the first doped polysilicon pattern 422A in the lateral direction, and the width M4B of the second conductive pillar CP42 may be determined by a width of the second doped polysilicon pattern 422B in the lateral direction. In an embodiment, the width M4A of the first conductive pillar CP41 at the backside surface 102B may be less than the width M4B of the second conductive pillar CP42 at the backside surface 102B. In other words, in some embodiments, a maximum width of the first conductive pillar CP41 may be less than a maximum width of the second conductive pillar CP42.

In some embodiments, each of the first conductive pillar CP41 included in the line isolation portion 420L and the second conductive pillar CP42 included in the corner isolation portion 420C may be used as a path through which a negative bias is applied to the pixel isolation structure DSA4 to prevent a dark current from being generated in the unit pixel PX. Because the first conductive pillar CP41 and the second conductive pillar CP42 are connected to each other and have a network-type planar structure, a negative bias may be easily applied to the entire pixel isolation structure DSA4 of the image sensor 400A through the first conductive pillar CP41 and the second conductive pillar CP42.

The line isolation portion 420L of the pixel isolation structure DSA4 may include a first insulating pattern 421 between the doped isolation liner 102P and the first doped polysilicon pattern 422A and the second insulating pattern 423. In the line isolation portion 420L, the second insulating pattern 423 may include a portion between the first doped polysilicon pattern 422A and the first metal pillar 426A and a portion facing a local device isolation film 110 with the first insulating pattern 421 therebetween.

The corner isolation portion 420C of the pixel isolation structure DSA4 may include the first insulating pattern 421 between the doped isolation liner 102P and the second doped polysilicon pattern 422B, the second insulating pattern 423 including a portion in contact with a partial region of the first insulating pattern 421, and a third insulating pattern 424 spaced apart from the first insulating pattern 421 with the second insulating pattern 423 therebetween. In some embodiments, the third insulating pattern 424 may be omitted. In the corner isolation portion 420C, the second insulating pattern 423 may include a first portion between the second doped polysilicon pattern 422B and the second metal pillar 426B and a second portion facing the local device isolation film 110 with the first insulating pattern 421 therebetween. The third insulating pattern 424 may be between a pair of local device isolation films 110 covering both sidewalls of the corner isolation portion 420C at an end of the corner isolation portion 420C, which is closest to the frontside surface 102F of the substrate 102. Constituent materials of the first insulating pattern 421, the second insulating pattern 423, and the third insulating pattern 424 may substantially and respectively are the same as those of the first insulating pattern 121 and the second insulating pattern 122, which are described with reference to FIGS. 3 to 6.

In the line isolation portion 420L of the pixel isolation structure DSA4, the first insulating pattern 421 and the second insulating pattern 423 may constitute a first insulating structure. In the corner isolation portion 420C of the pixel isolation structure DSA4, the first insulating pattern 421, the second insulating pattern 423, and the third insulating pattern 424 may constitute a second insulating structure. The first insulating structure included in the line isolation portion 420L may be integrally connected to the second insulating structure included in the corner isolation portion 420C.

A doped isolation liner 102P may be between the substrate 102 and the line isolation portion 420L and between the substrate 102 and the corner isolation portion 420C. In the line isolation portion 420L and the corner isolation portion 420C, the first insulating pattern 421 may be in contact with the doped isolation liner 102P. Each of the first doped polysilicon pattern 422A and the second doped polysilicon pattern 422B may be surrounded by the first insulating pattern 421 and be spaced apart from the doped isolation liner 102P and the local device isolation film 110 with the first insulating pattern 421 therebetween.

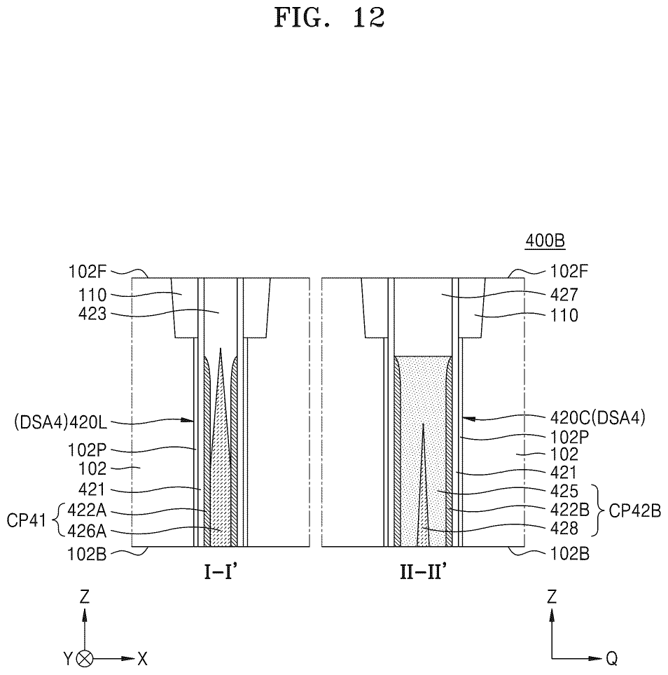

Referring to FIG. 12, the image sensor 400B may substantially have the same configuration as the image sensor 400A described with reference to FIG. 11. However, in the image sensor 400B, a second conductive pillar CP42B included in a corner isolation portion 420C of a pixel isolation structure DSA4 may include an inner polysilicon pattern 425 surrounded by a second doped polysilicon pattern 422B and a second metal pillar 428 surrounded by the inner polysilicon pattern 425. The inner polysilicon pattern 425 and the second metal pillar 428 may substantially and respectively have the same configurations as the inner polysilicon pattern 321 and the second metal pillar 326B described with reference to FIG. 9.

Because a first doped polysilicon pattern 422A and the second doped polysilicon pattern 422B are connected to each other and the inner polysilicon pattern 425 is in contact with each of the second doped polysilicon pattern 422B and the second metal pillar 428, the second conductive pillar CP42B may be electrically connectable to a first conductive pillar CP41 through the first doped polysilicon pattern 422A and the second doped polysilicon pattern 422B.

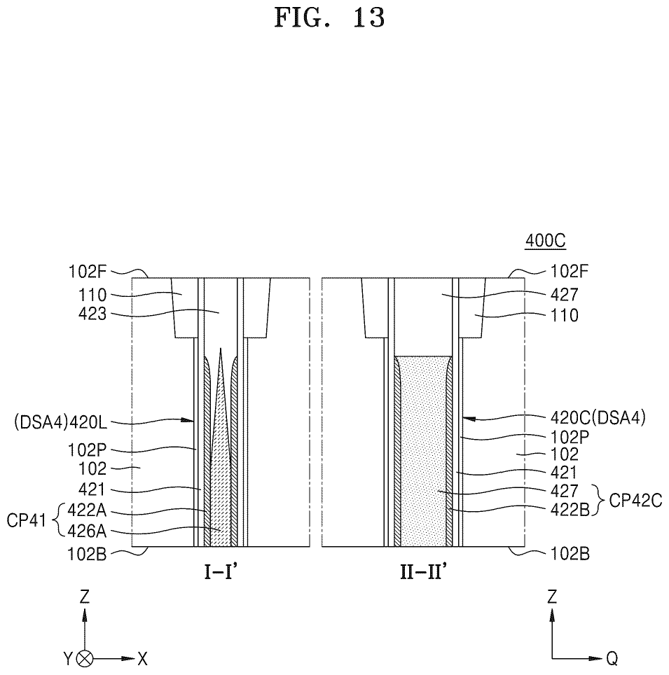

Referring to FIG. 13, the image sensor 400C may substantially have the same configuration as the image sensor 300A described with reference to FIG. 11. However, in the image sensor 400C, a second conductive pillar CP42C of the corner isolation portion 420C included in the pixel isolation structure DSA4 may include a second doped polysilicon pattern 422B and an inner polysilicon pattern 427 surrounded by the second doped polysilicon pattern 422B.

The inner polysilicon pattern 427 may substantially have the same configuration as the inner polysilicon pattern 321B described with reference to FIG. 10. The inner polysilicon pattern 427 may be at the center of the corner isolation portion 420C. The corner isolation portion 420C may not include a component corresponding to the second metal pillar 428 shown in FIG. 12. The corner isolation portion 420C may not include a metal.

Because the first doped polysilicon pattern 422A and the second doped polysilicon pattern 422B are connected to each other and the inner polysilicon pattern 427 is in contact with the second doped polysilicon pattern 422B, the second conductive pillar CP42C may be electrically connectable to a first conductive pillar CP41 through the first doped polysilicon pattern 422A and the second doped polysilicon pattern 422B.

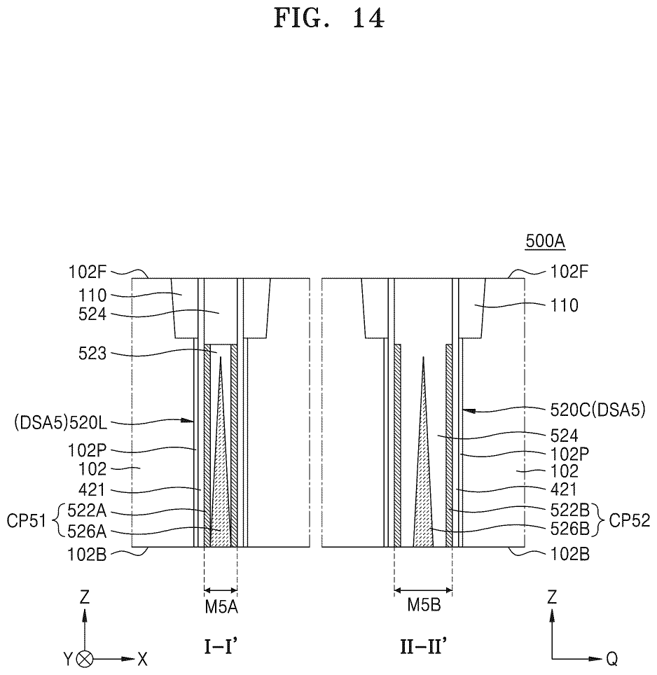

Referring to FIG. 14, the image sensor 500A may substantially have the same configuration as the image sensor 400A described with reference to FIG. 11. However, a pixel isolation structure DSA5 of the image sensor 500A may include a conductive pillar CP51 and CP52. The conductive pillar CP51 and CP52 may include a first conductive pillar CP51 included in a line isolation portion 520L and a second conductive pillar CP52 included in a corner isolation portion 520C. The first conductive pillar CP51 and the second conductive pillar CP52 may be integrally connected to each other to form a network-type planar structure.

The first conductive pillar CP51 included in the line isolation portion 520L may include a first metal pillar 526A and a first doped polysilicon pattern 522A including a portion in contact with the first metal pillar 526A. The second conductive pillar CP52 included in the corner isolation portion 520C may include a second metal pillar 526B and a second doped polysilicon pattern 522B spaced apart from the second metal pillar 526B. In the line isolation portion 520L, a first portion of the first doped polysilicon pattern 522A may be in contact with the first metal pillar 526A, and a second portion of the first doped polysilicon pattern 522A may be spaced apart from the first metal pillar 526A with a second insulating pattern 523 therebetween. In the corner isolation portion 520C, the second doped polysilicon pattern 522B may be spaced apart from the second metal pillar 526B with a third insulating pattern 524 therebetween.

The first metal pillar 526A and the second metal pillar 526B may substantially and respectively have the same configurations as the first metal pillar 126A and the second metal pillar 126B described with reference to FIGS. 3 to 6. The first metal pillar 526A and the second metal pillar 526B may be integrally connected to each other to form a network-type planar structure. A width of each of the first metal pillar 526A and the second metal pillar 526B in a lateral direction (or X direction in FIG. 14) may be variable in a vertical direction (Z direction). For example, each of the first metal pillar 526A and the second metal pillar 526B may have a tapered cross-sectional shape to have a greater width in the lateral direction (or X direction in FIG. 14) from a frontside surface 102F of a substrate 102 toward a backside surface 102B thereof. In some embodiments, each of the first metal pillar 526A and the second metal pillar 526B may reflect light, which is incident on the pixel isolation structure DSA5, toward the inside of a unit pixel PX adjacent thereto, and thus, a light gathering effect may improve in the unit pixel PX, and the sensitivity of the image sensor 500A may increase.

The first doped polysilicon pattern 522A and the second doped polysilicon pattern 522B may be connected to each other. Accordingly, the second conductive pillar CP52 may be electrically connectable to the first conductive pillar CP51 through the first doped polysilicon pattern 522A and the second doped polysilicon pattern 522B.

Each of the first doped polysilicon pattern 522A and the second doped polysilicon pattern 522B may include silicon doped with P+-type impurities. The P+-type impurities may include boron (B) ions. In the lateral direction (e.g., X direction in FIG. 11), a width M5A of the first conductive pillar CP51 in the line isolation portion 520L may be less than a width M5B of the second conductive pillar CP52 included in the corner isolation portion 520C. The width M5A of the first conductive pillar CP51 may be determined by a width of the first doped polysilicon pattern 522A in the lateral direction, and the width M5B of the second conductive pillar CP52 may be determined by a width of the second doped polysilicon pattern 522B in the lateral direction. In an embodiment, the width M5A of the first conductive pillar CP51 at the backside surface 102B may be less than the width M5B of the second conductive pillar CP52 at the backside surface 102B. In other words, in some embodiments, a maximum width of the first conductive pillar CP51 may be less than a maximum width of the second conductive pillar CP52.

In some embodiments, each of the first conductive pillar CP51 included in the line isolation portion 520L and the second conductive pillar CP52 included in the corner isolation portion 520C may be used as a path through which a negative bias is applied to the pixel isolation structure DSA5 to prevent a dark current from being generated in the unit pixel PX. Because the first conductive pillar CP51 and the second conductive pillar CP52 are connected to each other to form a network-type planar structure, a negative bias may be easily applied to the entire pixel isolation structure DSA5 of the image sensor 500A through the first conductive pillar CP51 and the second conductive pillar CP52.

The line isolation portion 520L of the pixel isolation structure DSA5 may include a first insulating pattern 421, the second insulating pattern 523, and a third insulating pattern 524. The first insulating pattern 421 may be between the doped isolation liner 102P and the first doped polysilicon pattern 522A. The second insulating pattern 523 may be spaced apart from the first insulating pattern 421 with the first doped polysilicon pattern 522A therebetween. The third insulating pattern 524 may overlap the first conductive pillar CP51 and the second insulating pattern 523 in the vertical direction (Z direction). In the line isolation portion 520L, the second insulating pattern 523 may include a portion between the first doped polysilicon pattern 522A and the first metal pillar 526A. The third insulating pattern 524 may face a local device isolation film 110 with the first insulating pattern 421 therebetween.

The corner isolation portion 520C of the pixel isolation structure DSA5 may include the first insulating pattern 421 and the third insulating pattern 524. The first insulating pattern 421 may include a portion between the doped isolation liner 102P and the second doped polysilicon pattern 522B. In the corner isolation portion 520C, the third insulating pattern 524 may include a portion between the second doped polysilicon pattern 522B and the second metal pillar 526B and a portion facing the local device isolation film 110 with the first insulating pattern 421 therebetween. Constituent materials of the first insulating pattern 421, the second insulating pattern 523, and the third insulating pattern 524 may substantially and respectively are the same as those of the first insulating pattern 121 and the second insulating pattern 122, which are described with reference to FIGS. 3 to 6.

In the line isolation portion 520L of the pixel isolation structure DSA5, the first insulating pattern 421, the second insulating pattern 523, and the third insulating pattern 524 may constitute a first insulating structure. In the corner isolation portion 520C of the pixel isolation structure DSA5, the first insulating pattern 421 and the third insulating pattern 524 may constitute a second insulating structure. The first insulating structure included in the line isolation portion 520L may be integrally connected to the second insulating structure included in the corner isolation portion 520C.

A doped isolation liner 102P may be between the substrate 102 and the line isolation portion 520L and between the substrate 102 and the corner isolation portion 520C. In the line isolation portion 520L and the corner isolation portion 520C, the first insulating pattern 421 may be in contact with the doped isolation liner 102P. Each of the first doped polysilicon pattern 522A and the second doped polysilicon pattern 522B may be surrounded by the first insulating pattern 421 and be spaced apart from the doped isolation liner 102P and the local device isolation film 110 with the first insulating pattern 421 therebetween.

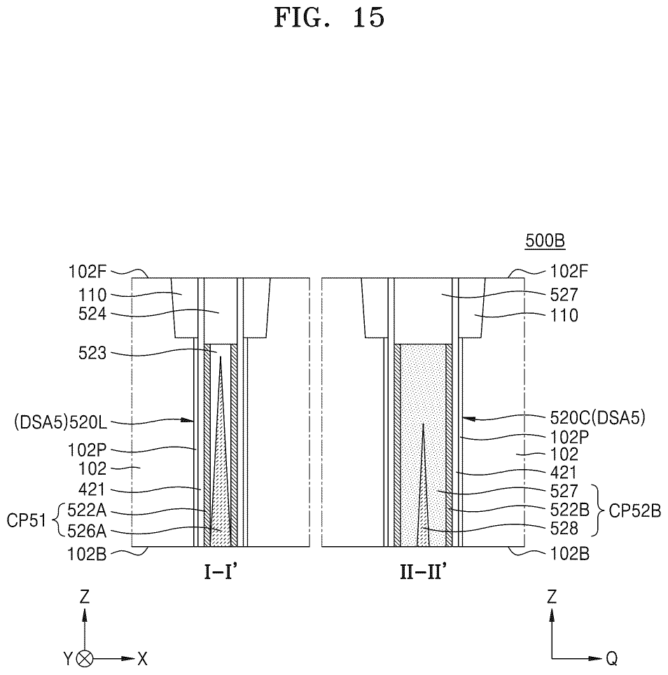

Referring to FIG. 15, the image sensor 500B may substantially have the same configuration as the image sensor 500A described with reference to FIG. 14. However, in the image sensor 500B, a second conductive pillar CP52B included in a corner isolation portion 520C of a pixel isolation structure DSA5 may include an inner polysilicon pattern 527 surrounded by a second doped polysilicon pattern 522B and a second metal pillar 528 surrounded by the inner polysilicon pattern 527. The inner polysilicon pattern 527 and the second metal pillar 528 may substantially and respectively have the same configurations as the inner polysilicon pattern 321 and the second metal pillar 326B described with reference to FIG. 9.

Because a first doped polysilicon pattern 522A and the second doped polysilicon pattern 522B are connected to each other and the inner polysilicon pattern 527 is in contact with each of the second doped polysilicon pattern 522B and the second metal pillar 528, the second conductive pillar CP52B may be electrically connectable to the first conductive pillar CP51 through the first doped polysilicon pattern 522A and the second doped polysilicon pattern 522B.

Exemplary structures of the image sensors 100B, 300A, 300B, 400A, 400B, 400C, 500A, and 500B described with reference to FIGS. 7 to 15 may constitute a portion of the image sensor 100 shown in FIGS. 1 and 2. The image sensors 100B, 300A, 300B, 400A, 400B, 400C, 500A, and 500B described with reference to FIGS. 7 to 15 may include the pixel isolation structures DSA, DSA2, DSA3, DSA4, and DSA5, each of which passes through the substrate 102 in the vertical direction (Z direction) to define the plurality of unit pixels PX) and has the network-type planar structure. Therefore, like in the image sensor 100A described with reference to FIGS. 3 to 6, a light gathering effect of each of the plurality of unit pixels PX may improve, and problems (e.g., shift, collapse, and/or deformation) of the pixel isolation structures DSA, DSA2, DSA3, DSA4, and DSA5 and peripheral components thereof may be prevented during and/or after the manufacture of the image sensors 100A, 100B, 300A, 300B, 400A, 400B, 400C, 500A, and 500B. Furthermore, by applying a negative bias to the pixel isolation structures DSA, DSA2, DSA3, DSA4, and DSA5, characteristics (e.g., a dark current and white spots) of each of all the unit pixels PX defined by the pixel isolation structures DSA, DSA2, DSA3, DSA4, and DSA5 may be effectively controlled. Accordingly, the sensitivity and resolution of the image sensors 100A, 100B, 300A, 300B, 400A, 400B, 400C, 500A, and 500B may improve.

Next, a method of manufacturing an image sensor, according to embodiments, is described.

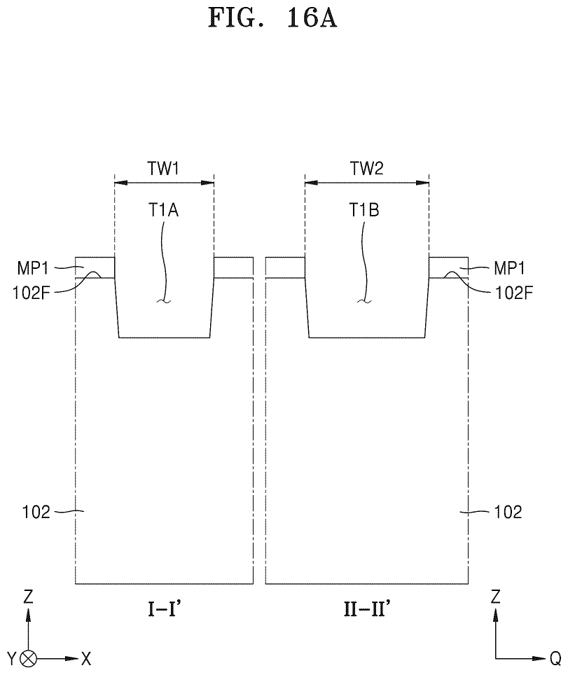

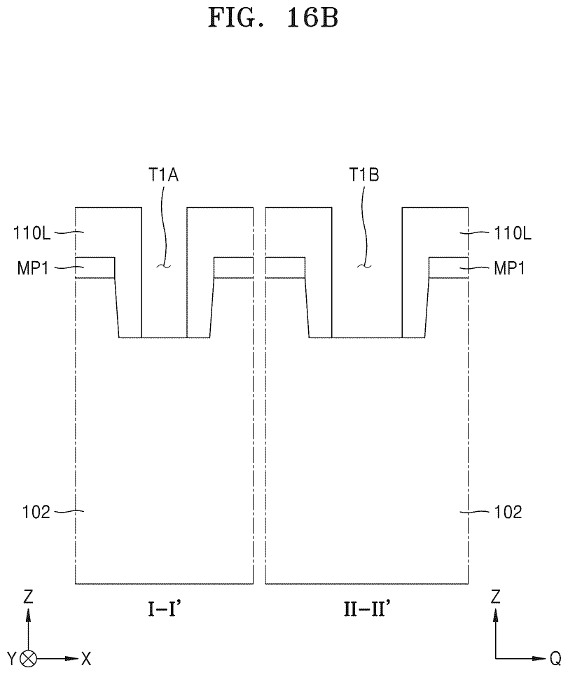

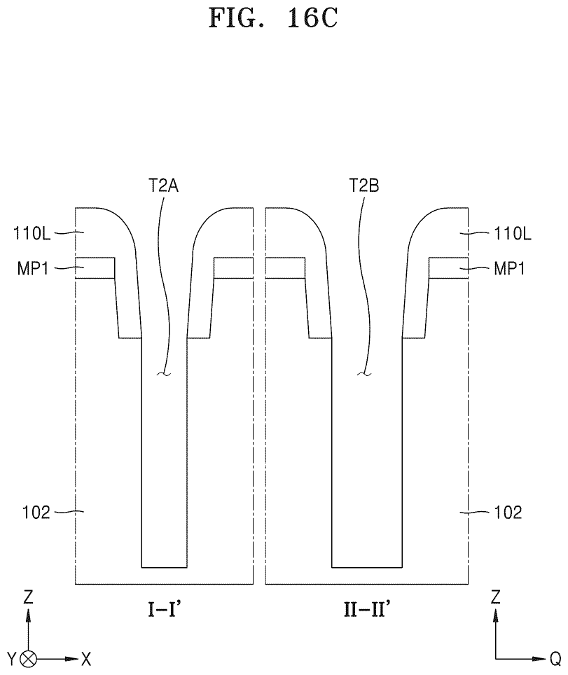

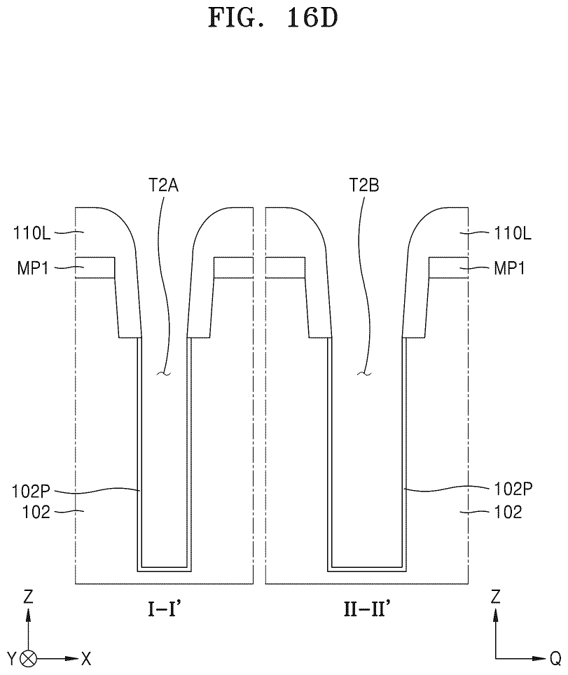

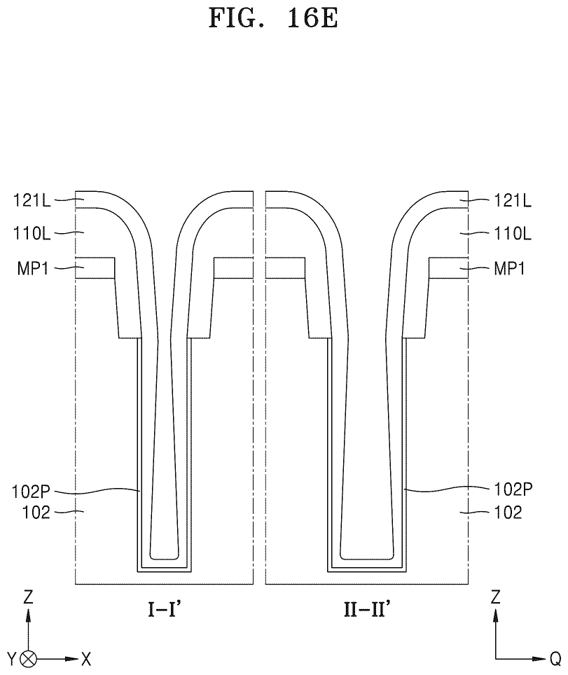

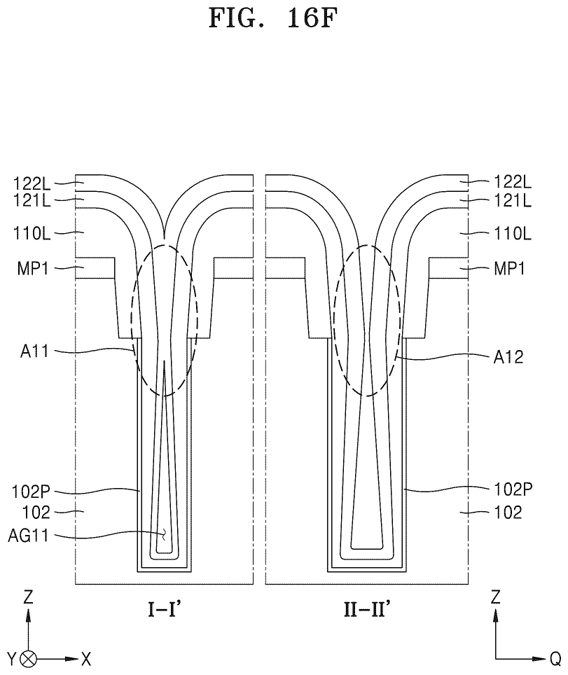

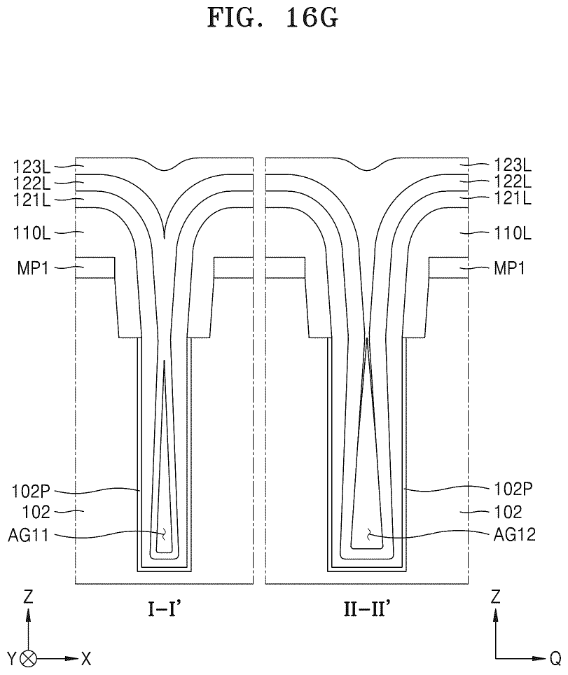

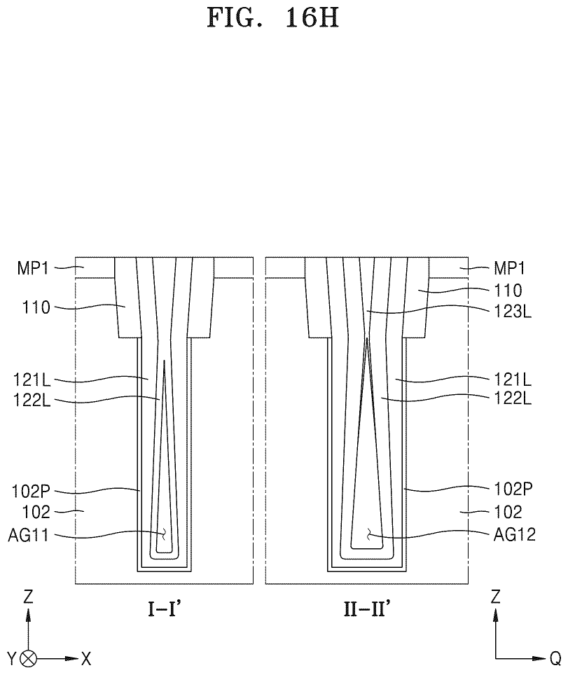

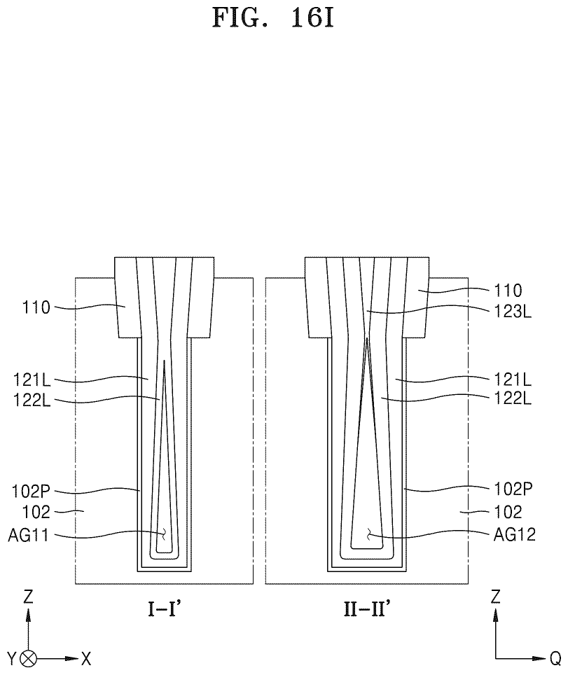

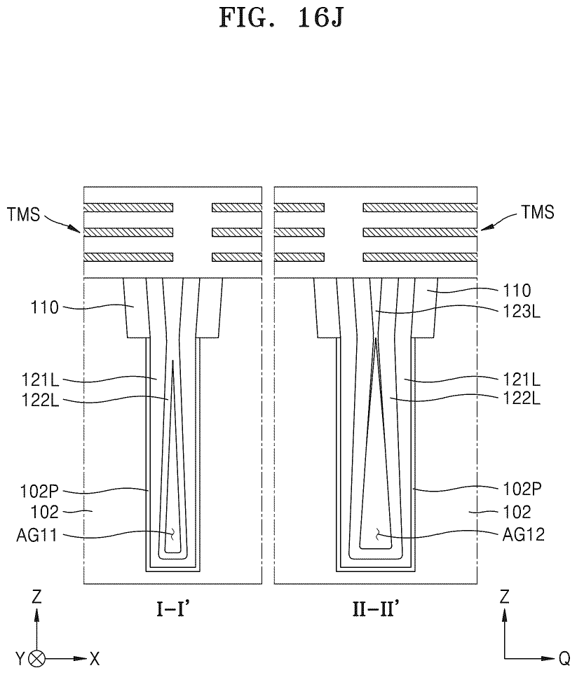

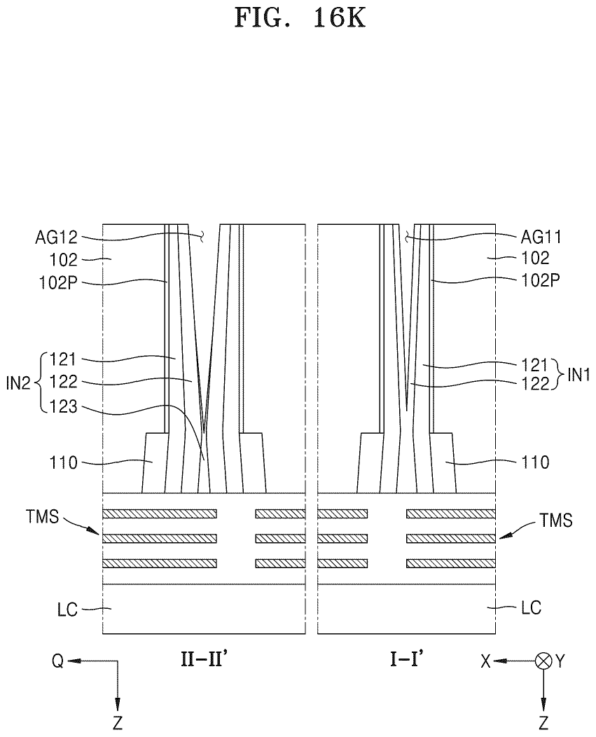

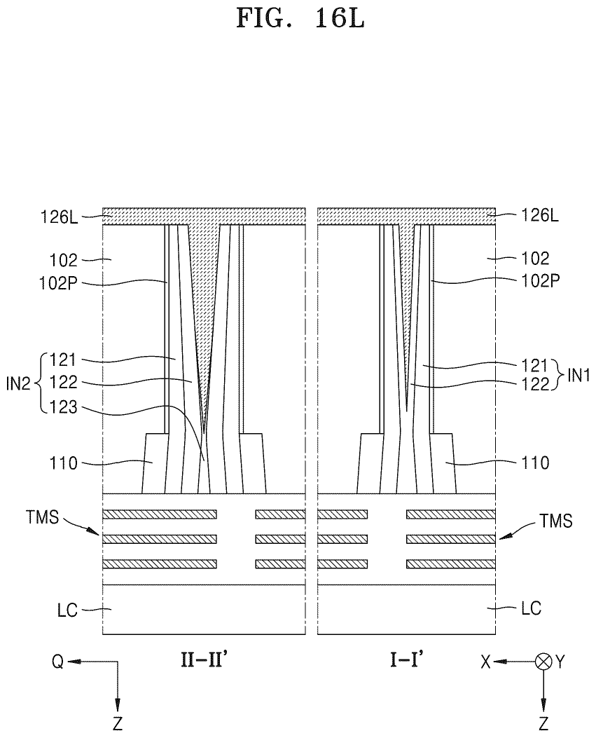

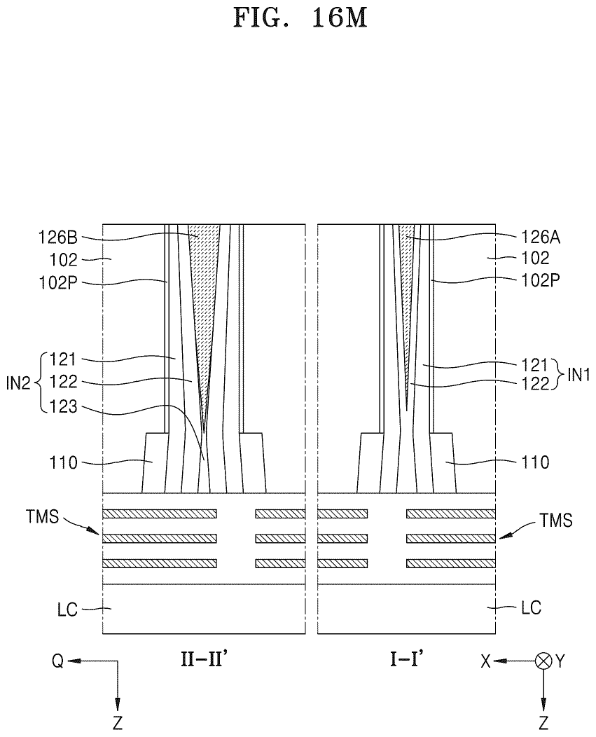

FIGS. 16A to 16M are cross-sectional views of a process sequence of a method of manufacturing an image sensor, according to embodiments. FIGS. 16A to 16M illustrate cross-sectional configurations of portions corresponding to cross-sections taken along lines I-I′ and II-II′ of FIG. 4, according to a process sequence. An example of a method of manufacturing the image sensor 100A shown in FIGS. 3 to 6 is described with reference to FIGS. 16A to 16M. In FIGS. 16A to 16M, the same reference numerals are used to denote the same elements as in FIGS. 1 to 6, and detailed descriptions thereof are omitted for conciseness.

Referring to FIG. 16A, a mask pattern MP1 may be formed to cover partial regions of a frontside surface 102 of a substrate 102, and the partial regions of the substrate 102 may be etched by using the mask pattern MP1 as an etch mask, and thus, shallow trenches T1A and T1B may be formed in regions of the substrate 102 in which the line isolation portion (refer to 120L in FIG. 4) and a corner isolation portion (refer to 120C in FIG. 4) will be formed. A width TW1 of a portion of the shallow trenches TIA and T1B, which corresponds to the line isolation portion (refer to 120L in FIG. 6) may be less than a width TW2 of a portion of the shallow trenches T1A and T1B, which corresponds to the corner isolation portion 120C. In some embodiments, the mask pattern MP1 may include a buffer oxide film and a silicon nitride film, which are sequentially stacked on the substrate 102.

Referring to FIG. 16B, a local insulating pattern 110L may be formed on the resultant structure of FIG. 16A. The formation of the local insulating pattern 110L may include forming a silicon oxide film to cover the resultant structure of FIG. 16A and patterning the silicon oxide film to expose a portion of the substrate 102 at bottom surfaces of the shallow trenches T1A and T1B.

Referring to FIG. 16C, partial regions of the substrate 102 may be etched using the local insulating pattern 110L as an etch mask to form deep trenches T2A and T2B. A width of a portion of the deep trenches T2A and T2B, which corresponds to the line isolation portion 120L, may be less than a width of a portion of the deep trenches T2A and T2B, which corresponds to the corner isolation portion 120C. While the substrate 102 is being etched to form the deep trenches T2A and T2B, a portion of the local insulating pattern 110L may be consumed, and thus, an aperture width of the local insulating pattern 110L may increase near entrances of the deep trenches T2A and T2B.

Referring to FIG. 16D, after an ion implantation process may be performed on the substrate 102 through the deep trenches T2A and T2B, the resultant structure may be annealed, and thus, a doped isolation liner 102P may be formed on surfaces of the substrate 102, which are exposed at the deep trenches T2A and T2B.

Referring to FIG. 16E, a first insulating film 121L may be formed to cover the doped isolation liner 102P inside each of the deep trenches T2A and T2B and an exposed surface of the local insulating pattern 110L. A constituent material of the first insulating film 121L is the same as that of a first insulating pattern 121, which is described above.

The first insulating film 121L may be formed by using an atomic layer deposition (ALD) process, a chemical vapor deposition (CVD) process, or a combination thereof. In some embodiments, the formation of the first insulating film 121L may include, initially, forming a portion of the first insulating film 121L by using an ALD process and forming a remaining portion of the first insulating film 121L by using a CVD process. During the formation of the remaining portion of the first insulating film 121L, a deposition process of forming the first insulating film 121L may be performed under conditions where step coverage characteristics are relatively deteriorated. As a result, after the first insulating film 121L is formed, a thickness of the first insulating film 121L may become greater at the entrances of the deep trenches T2A and T2B (i.e., at boundaries between the shallow trenches T1A and T1B and the deep trenches T2A and T2B) than in other portions. Thus, opening widths of the entrances of the deep trenches T2A and T2B may be smaller than widths of other portions of the deep trenches T2A and T2B.

In some embodiments, the first insulating film 121L may include a silicon oxide film, a silicon nitride film, or a combination thereof. The formation of the first insulating film 121L may include forming a silicon oxide film using a low-pressure CVD (LPCVD) system by a middle temperature oxidation (MTO) or a high temperature oxidation (HTO) process. In this case, monosilane or disilane may be used as a silicon precursor. The deposition process of forming the first insulating film 121L may be performed at a temperature selected in a range of about 700° C. to about 850° C.

Referring to 16F, a second insulating film 122L may be formed on the resultant structure of FIG. 16E. A constituent material of the second insulating film 122L may be the same as that of the second insulating pattern 122, which is described above. The second insulating film 122L may be formed by using an ALD process, a CVD process, or a combination thereof.

During the formation of the second insulating film 122L, it may be relatively difficult for source materials required to form the second insulating film 122L to reach the inside of the deep trench (refer to T2A in FIG. 16D) because the inside of a portion of the deep trench T2A, which corresponds to the line isolation portion (refer to 120L in FIG. 6), is narrower and deeper than the inside of a portion of the deep trench (refer to T2B in FIG. 16D), which corresponds to the corner isolation portion 120C. Accordingly, a portion of the second insulating film 122L, which is formed inside the deep trench T2A, may have a smaller thickness than other portions of the second insulating film 122L, and the entrance of the deep trench T2A, which is a boundary between the shallow trench T1A and the deep trench T2A, may be blocked by the second insulating film 122L as shown in a dashed area A11 of FIG. 16F. As a result, a first air gap AG11 defined by the second insulating film 122L may be formed inside the deep trench T2A. As used herein, the term “air” may refer to the atmosphere or other gases that may be during a manufacturing process. During the formation of the second insulating film 122L, the entrance of the deep trench T2B in a portion of the deep trenches T2A and T2B, which corresponds to the corner isolation portion 120C, may remain connected to the outside as shown in a dashed area A12 of FIG. 16F.

In some embodiments, the formation of the second insulating film 122L may include forming a silicon oxide film by performing an ALD process under conditions of relatively good step coverage characteristics. In this case, diisopropylamino silane (DIPAS) or hexachorodisilane (HCDS) may be used as the silicon precursor, without being limited thereto.

Referring to FIG. 16G, a third insulating film 123L may be formed on the resultant structure of FIG. 16F. A constituent material of the third insulating film 123L may be the same as that of the third insulating pattern 123, which is described above. The third insulating film 123L may be formed by using an ALD process, a CVD process, or a combination thereof. In some embodiments, after the third insulating film 123L is formed, an annealing process may be performed to densify the third insulating film 123L.

During the formation of the third insulating film 123L, an entrance of the deep trench T2B, which is a boundary between the shallow trench T1B and the deep trench T2B, may be blocked by the third insulating film 123L in a portion corresponding to the corner isolation portion 120C. As a result, a second air gap AG12 may be formed inside the deep trench T2B.

Referring to FIG. 16H, the resultant structure of FIG. 16G may be planarized by using a chemical mechanical polishing (CMP) process to expose a top surface of the mask pattern MP1.

Referring to FIG. 16I, the mask pattern MP1 may be removed from the resultant structure of FIG. 16H to expose the substrate 102.

Referring to FIG. 16J, as shown in FIGS. 3 and 5, various processes required for the manufacture of the image sensor 100A may be performed on the resultant structure of FIG. 16I. For example, a process of forming a plurality of photodiodes PD in a sensor array area SA by implanting impurity ions into the substrate 102 from a frontside surface 102F of the substrate 102, a process of forming a plurality of transistors including a transfer transistor TX by forming a gate dielectric film and a plurality of gate structures on the frontside surface 102F of the substrate 102, and a process of forming a floating diffusion region FD by implanting impurity ions into a partial region of the substrate 102 from the frontside surface 102F of the substrate 102 may be performed. The plurality of gate structures may include gate structures that constitute transistors required to drive a plurality of unit pixels PX included in the image sensor 100. Thereafter, a wiring structure TMS may be formed to cover the plurality of gate structures. Although the wiring structure TMS is illustrated in a simplified manner in FIG. 16J and drawings described later, a detailed configuration of the wiring structure TMS is the same as that described with reference to FIGS. 3 and 5.

Referring to FIG. 16K, in the resultant structure of FIG. 16J, a first semiconductor chip LC may be bonded onto the wiring structure TMS by using the bonding layer (refer to BL in FIG. 3) included in the wiring structure TMS, and the obtained resultant structure may be rotated such that the substrate 102 faces upward in a vertical direction (Z direction). Thereafter, an exposed portion of the substrate 102 and a portion of each of the doped isolation liner 102P, the first insulating film 121L, and the second insulating film 122L may be removed by using a mechanical grinding process, a CMP process, a wet etching process, or a combination thereof, and thus, the first air gap AG11 and the second air gap AG12 may be exposed to the outside. As a result, remaining portions of the first insulating film 121L, the second insulating film 124L, and the third insulating film 123L may constitute the first insulating pattern 121, the second insulating pattern 124, and the third insulating pattern 123 Although the first semiconductor chip LC is illustrated in a simplified manner in FIG. 16K and drawings described later, a detailed configuration of the first semiconductor chip LC is the same as that described with reference to FIG. 3.

Referring to FIG. 16L, in the resultant structure of FIG. 16K, a metal film 126L may be formed to fill the first air gap AG11 and the second air gap AG12 and cover a backside surface 102B of the substrate 102. A constituent material of the metal film 126L is the same as those of the first metal pillar 126A and the second metal pillar 126B, which are described with reference to FIG. 6.

Referring to FIG. 16M, a portion of the metal film 126L may be removed from the resultant structure of FIG. 16L to expose the backside surface (refer to 102B in FIGS. 5 and 6) of the substrate 102, and the first metal pillar 126A filling the first air gap AG11 and the second metal pillar 126B filling the second air gap AG12 may be formed.

Thereafter, as shown in FIG. 3, a backside insulating film 162 may be formed on the backside surface 102B of the substrate 102 and one end surface of each of a plurality of pixel isolation structures DSA, and a plurality of grid patterns 164, a first protective film 166, and a plurality of color filters 170 may be formed on the backside insulating film 162 in the active sensor area APS. Afterwards, a microlens 180 and a second protective film 182 may be formed on the plurality of color filters 170 in the active pixel sensor area APS, and thus, the image sensor 100A shown in FIGS. 3 to 6 may be manufactured.

The image sensor 100B shown in FIG. 7 may be manufactured by using the processes described with reference to FIGS. 16A to 16M. However, by controlling step coverage characteristics in a deposition process of forming the second insulating film 122L described with reference to FIG. 16F, the second insulating film 122L may be formed only in a partial region of the inside of the deep trench T2A, which is close to the entrance of the deep trench T2A. The processes described with reference to FIGS. 16G to 16M may be performed on the resultant structure, and thus, the image sensor 100B shown in FIG. 7 may be manufactured.

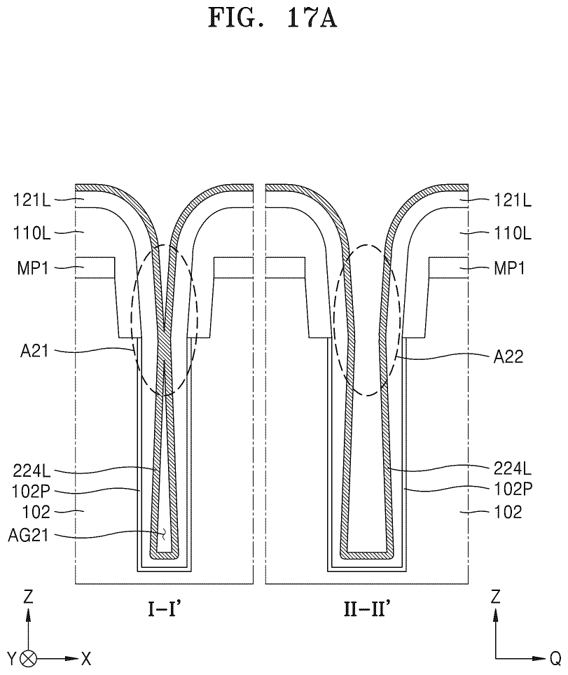

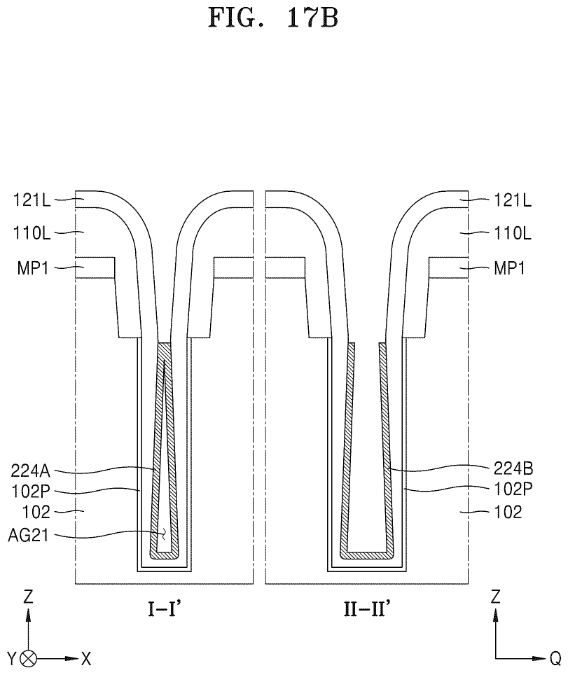

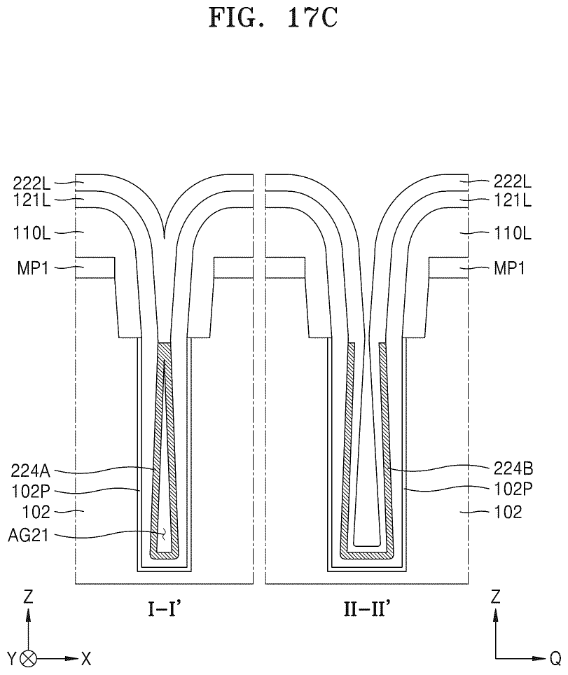

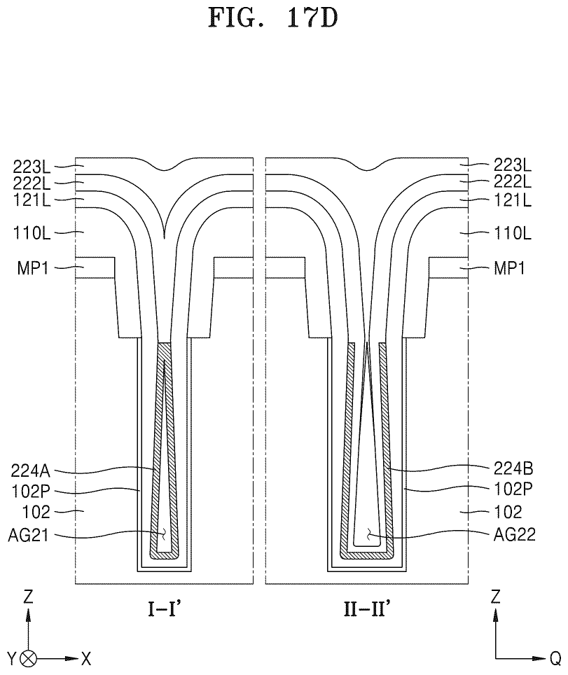

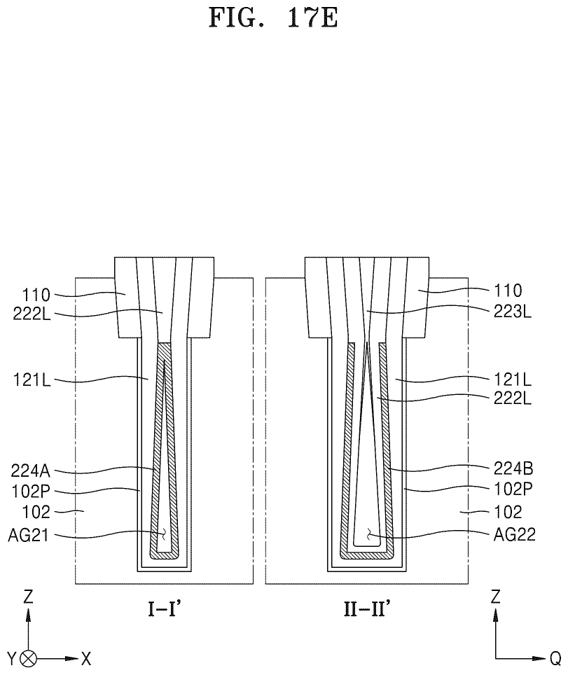

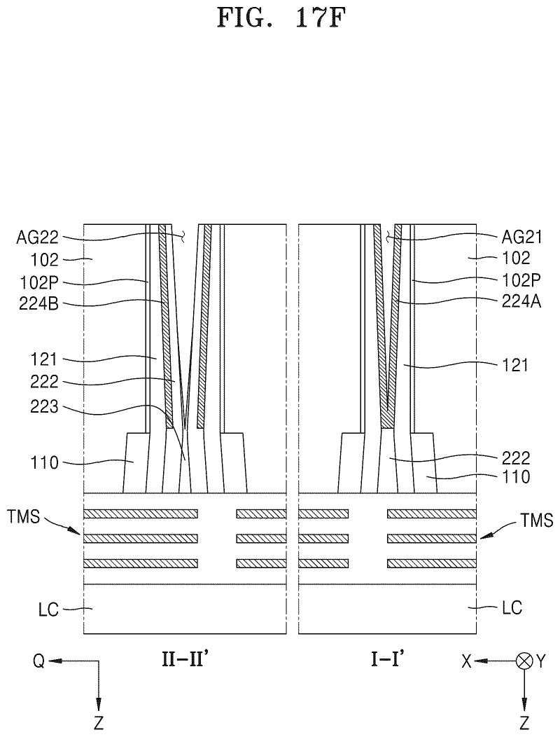

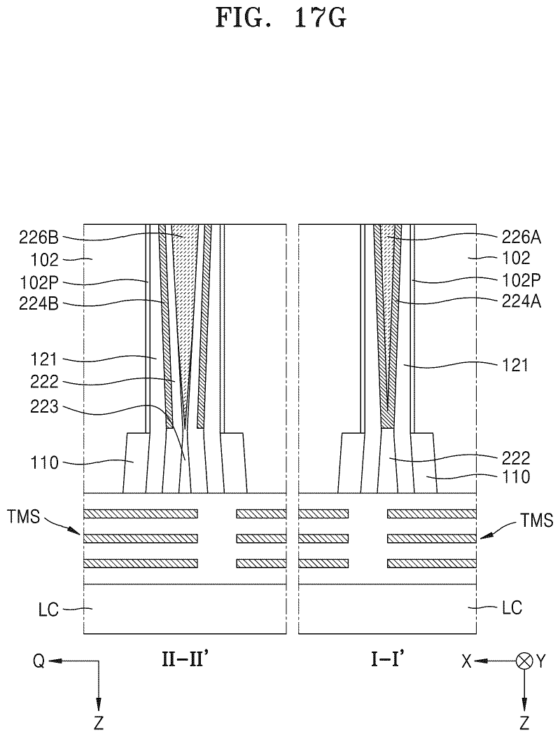

FIGS. 17A to 17G are cross-sectional views of a process sequence of a method of manufacturing an image sensor, according to embodiments. FIGS. 17A to 17G illustrate cross-sectional configurations of portions corresponding to cross-sections taken along lines I-I′and II-II′ of FIG. 4, according to a process sequence. An example of a method of manufacturing the image sensor 200 shown in FIG. 8 is described with reference to FIGS. 17A to 17G. In FIGS. 17A to 17G, the same reference numerals are used to denote the same elements as in FIGS. 1 to 8, and detailed descriptions thereof are omitted for conciseness.

Referring to FIG. 17A, after the processes described with reference to FIGS. 16A to 16E are performed, a doped polysilicon liner 224L may be formed to conformally cover exposed surfaces in the resultant structure of FIG. 16E. In some embodiments, the doped polysilicon liner 224L may be formed by using a CVD process or an ALD process. In some embodiments, to conformally form the doped polysilicon liner 224L to a uniform thickness on inner surfaces of the deep trenches T2A and T2B (refer to FIG. 16C), a Si seeding process may be performed to supply Si seeds to exposed surfaces of the resultant structure of FIG. 16E before the doped polysilicon liner 224L is formed. A Si precursor used for the Si seeding process may include, for example, diisopropylamino silane (DIPAS) and hexachorodisilane (HCDS), without being limited thereto.

As shown in a dashed area A21 of FIG. 17A, an entrance of the deep trench T2A, which is a boundary between the shallow trench TIA and the deep trench T2A, may be blocked by the doped polysilicon liner 224L in a portion of the doped polysilicon liner 224L, which corresponds to the line isolation portion (refer to 220L in FIG. 8). As a result, a first air gap AG1 defined by the doped polysilicon liner 224L may be formed inside the deep trench T2A. After the doped polysilicon liner 224L is formed, an entrance of a portion of the deep trench T2B, which corresponds to the corner isolation portion (refer to 220C in FIG. 8), may remain connected to the outside as shown in a dashed area A22 of FIG. 17A.

Referring to FIG. 17B, an exposed upper portion of the doped polysilicon liner 224L may be partially removed from the resultant structure of FIG. 17A to expose an upper portion of the first insulating film 121L. As a result, a first portion of the doped polysilicon liner 224L may remain as a first doped polysilicon pattern 224A defining the first air gap AG21 inside the deep trench T2A, and a second portion of the doped polysilicon liner 224L may remain as a second doped polysilicon pattern 224B covering the first insulating film 121L inside the deep trench T2B.

Referring to FIG. 17C, a second insulating film 222L may be formed on the resultant structure of FIG. 17B. A constituent material of the second insulating film 222L is the same as that of the second insulating pattern 222, which is described above. The second insulating film 222L may be formed by using an ALD process, a CVD process, or a combination thereof.

In some embodiments, because the deep trench T2A is blocked by the first doped polysilicon pattern 224A defining the first air gap AG21, the second insulating film 222L may be formed inside the deep trench T2B but may not be formed inside the deep trench T2A. In some embodiments, because a portion of the deep trench T2A, which corresponds to the line isolation portion 220L, is connected to the portion of the deep trench T2B, which corresponds to the corner isolation portion 220C, reactants required to form the second insulating film 222L may move to the deep trench T2A through the deep trench T2B during the formation of the second insulating film 222L. In this case, a portion of the second insulating film 222L may be formed also inside the first air gap AG21 in the deep trench T2A. The portion of the second insulating film 222L, which is formed inside the first air gap AG21, may be removed by a cleaning process after subsequent processes (e.g., a process described below with reference to FIG. 17F) or may not be removed but remain inside the first air gap AG21.

Referring to FIG. 17D, a third insulating film 223L may be formed on the resultant structure of FIG. 17C. A constituent material of the third insulating film 223L is the same as that of the third insulating pattern 223, which is described above. The third insulating film 223L may be formed by using an ALD process, a CVD process, or a combination thereof. In some embodiments, after the third insulating film 223L is formed, an annealing process may be performed to densify the third insulating film 223L.

During the formation of the third insulating film 223L, the entrance of the deep trench T2B, which is a boundary between the shallow trench T1B and the deep trench T2B, may be blocked by the third insulating film 223L in a portion corresponding to the corner isolation portion (refer to 220C in FIG. 8). As a result, a second air gap AG22 may be formed inside the deep trench T2B.

Referring to FIG. 17E, processes similar to those described with reference to FIGS. 16H and 16I may be performed on the resultant structure of FIG. 17D to remove the mask pattern MP1 and expose the substrate 102.

Referring to FIG. 17F, processes similar to those described with reference to FIGS. 16J and 16K may be performed on the resultant structure of FIG. 17E to expose the first air gap AG21 and the second air gap AG22 to the outside.

Referring to FIG. 17G, processes similar to those described with reference to FIGS. 16L and 16M may be performed on the resultant structure of FIG. 17F to form a first metal pillar 226A filling the first air gap AG11 and a second metal pillar 226B filling the second air gap AG22. Thereafter, subsequent processes described with reference to FIG. 16M may be performed on the resultant structure of FIG. 17G, and thus, the image sensor 200 shown in FIG. 8 may be manufactured.

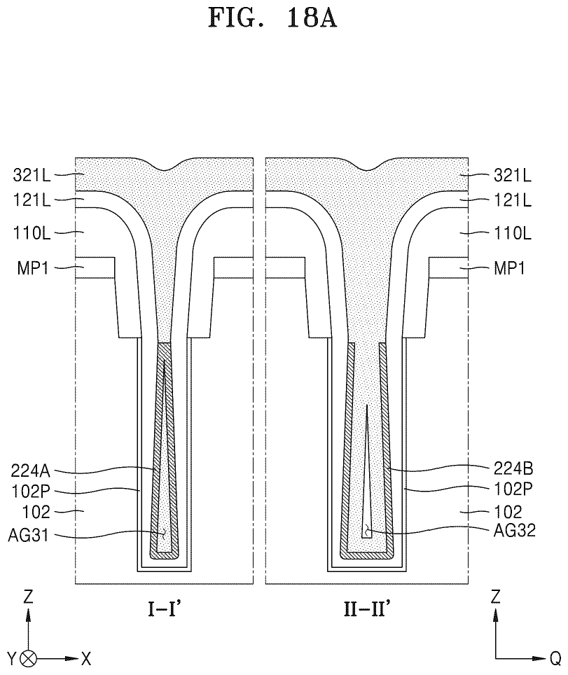

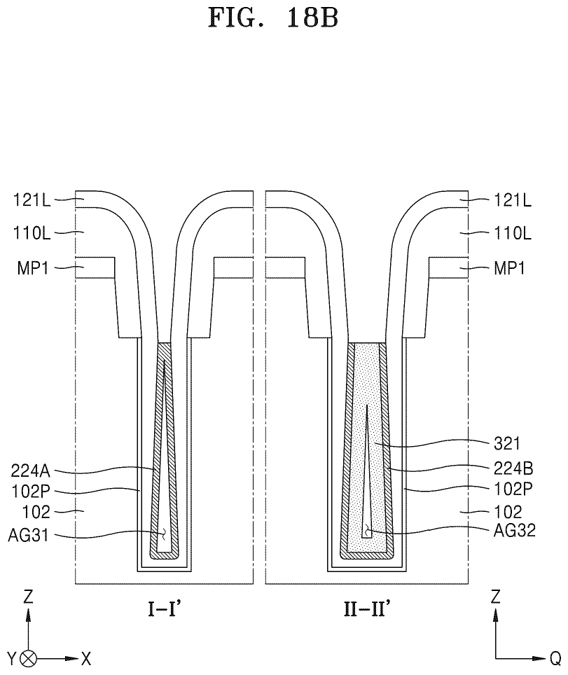

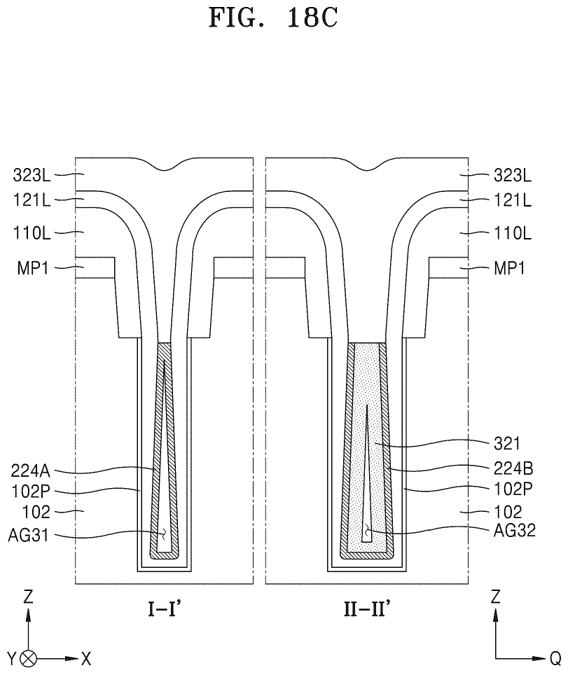

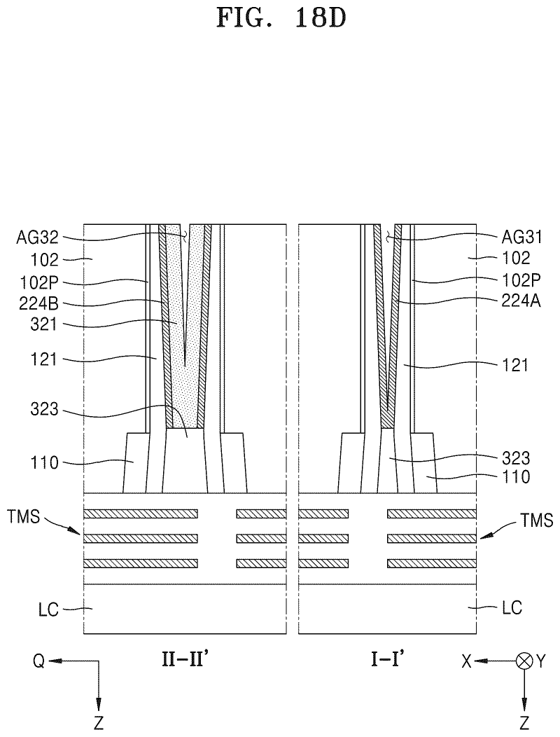

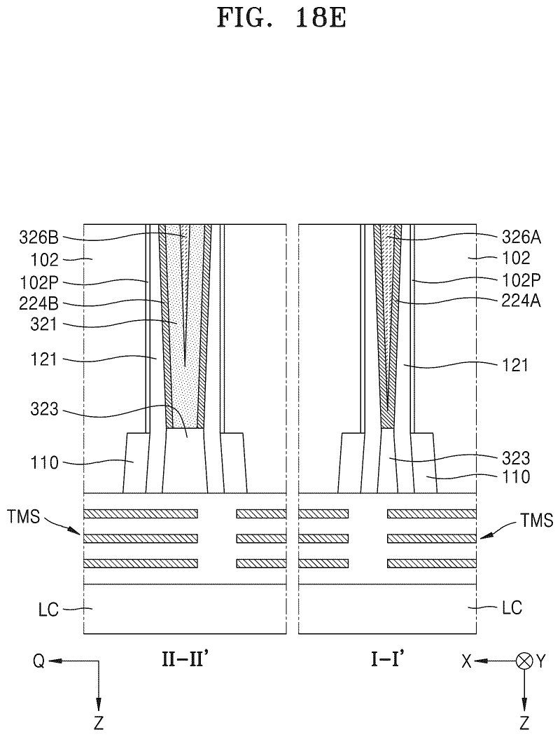

FIGS. 18A to 18E are cross-sectional views of a process sequence of a method of manufacturing an image sensor, according to embodiments. FIGS. 18A to 18E illustrate cross-sectional configurations of portions corresponding to cross-sections taken along lines I-I′and II-II′ of FIG. 4, according to a process sequence. An example of a method of manufacturing the image sensor 300A shown in FIG. 9 is described with reference to FIGS. 18A to 18E. In FIGS. 18A to 18E, the same reference numerals are used to denote the same elements as in FIGS. 1 to 9, and detailed descriptions thereof are omitted for conciseness.

Referring to FIG. 18A, processes similar to those described with reference to FIGS. 17A and 17B may be performed, and thus, a first doped polysilicon pattern 224A and a second doped polysilicon pattern 224B may be formed. The first doped polysilicon pattern 224A may define a first air gap AG31 inside a portion of a deep trench T2A, which corresponds to a line isolation portion (refer to 320L in FIG. 9). The second doped polysilicon pattern 224B may covers a first insulating film 121L inside a portion of a deep trench T2B, which corresponds to a corner isolation portion (refer to 320C in FIG. 9).

Thereafter, an inner polysilicon film 321L may be formed on the resultant structure including the first doped polysilicon pattern 224A and the second doped polysilicon pattern 224B. In some embodiments, the inner polysilicon film 321L may include undoped polysilicon. A portion of the inner polysilicon film 321L, which corresponds to the line isolation portion (refer to 320L in FIG. 9), may be formed to contact the first doped polysilicon pattern 224A, and a portion of the inner polysilicon film 321L, which corresponds to the corner isolation portion (refer to 320C in FIG. 9) may be formed to contact the second doped polysilicon pattern 224B. Thus, even when the inner polysilicon film 321L is formed to include undoped polysilicon, processes described below may be performed, and thus, a dopant may diffuse from the first doped polysilicon pattern 224A and the second doped polysilicon pattern 224B into the inner polysilicon film 321L. Accordingly, the inner polysilicon film 321L may be doped with the dopant through a process described below.

During the formation of the inner polysilicon film 321L, an entrance of the deep trench T2B, which is a boundary between a shallow trench T1B and the deep trench T2B, may be blocked by the inner polysilicon film 321L in a portion corresponding to the corner isolation portion (refer to 320C in FIG. 9). Aa a result, a second air gap AG32 may be formed inside the deep trench T2B.

Referring to FIG. 18B, a portion of the inner polysilicon film 321L may be removed from the resultant structure of FIG. 18A so that the first doped polysilicon pattern 224A and the second doped polysilicon pattern 224B may be exposed. Thus, an upper portion of the first insulating film 121L may exposed. As a result, a portion of the inner polysilicon film 321L may remain as an inner polysilicon pattern 321 defining the second air gap AG32 inside a portion of the deep trench T2B, which corresponds to the corner isolation portion (refer to 320C in FIG. 9).

Referring to FIG. 18C, a second insulating film 323L may be formed on the resultant structure of FIG. 18B. A constituent material of the second insulating film 323L is the same as that of the second insulating pattern 323, which is described above. The second insulating film 323L may be formed by using a CVD process. In some embodiments, after the second insulating film 323L is formed, an annealing process may be performed to densify the second insulating film 323L.

Referring to FIG. 18D, processes similar to those described with reference to FIGS. 16H to 16K may be performed on the resultant structure of FIG. 18C to expose the first air gap AG31 and the second air gap AG32 to the outside.

Referring to FIG. 18E, processes similar to those described with reference to FIGS. 16L and 16M may be performed on the resultant structure of FIG. 18D to form a first metal pillar 326A filling the first air gap AG31 and a second metal pillar 326B filling the second air gap AG32. Thereafter, subsequent processes described with reference to FIG. 16M may be performed on the resultant structure of FIG. 18E, and thus, the image sensor 300A shown in FIG. 9 may be manufactured.

To manufacture the image sensor 300B shown in FIG. 10, in the process described with reference to FIG. 18A, the inner polysilicon film 321L may be formed such that the second air gap AG32 is not formed inside a portion of the deep trench T2B, which corresponds to the corner isolation portion (refer to 320C in FIG. 10), and the inside of the deep trench T2B defined by the second doped polysilicon pattern 224B is filled by the inner polysilicon film 321L without an air gap. Thereafter, processes described with reference to FIGS. 18B to 18E may be performed on the resultant structure containing the inner polysilicon film 321L, which is similar to the resultant structure of FIG. 18A but does not include the second air gap AG32 in the inner polysilicon film 321L, and thus, the image sensor 300B shown in FIG. 10 may be manufactured. A portion of the inner polysilicon film 321L, which fills the deep trench T2B, may remain as an inner polysilicon pattern 321B of the image sensor 300B.

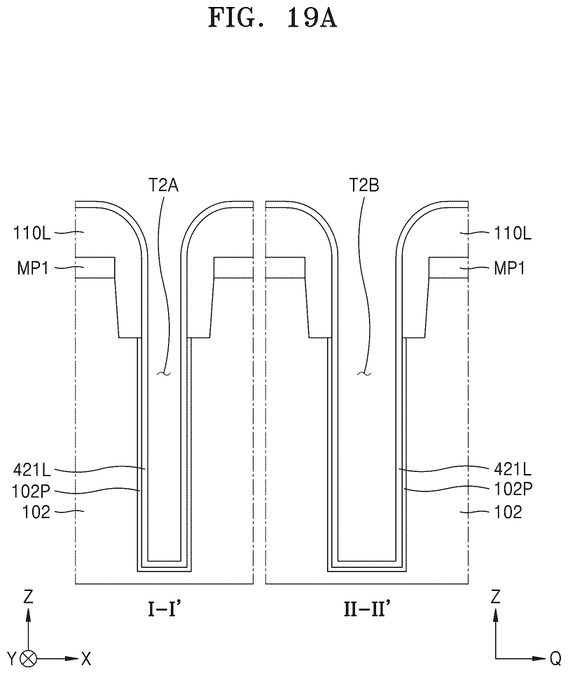

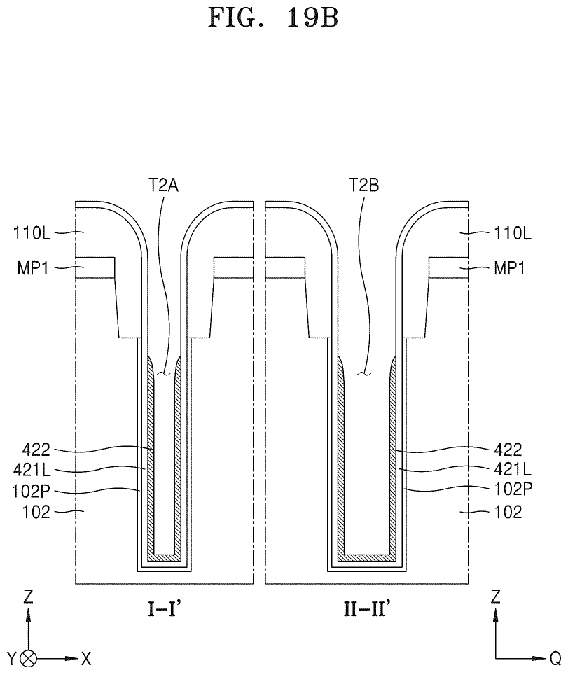

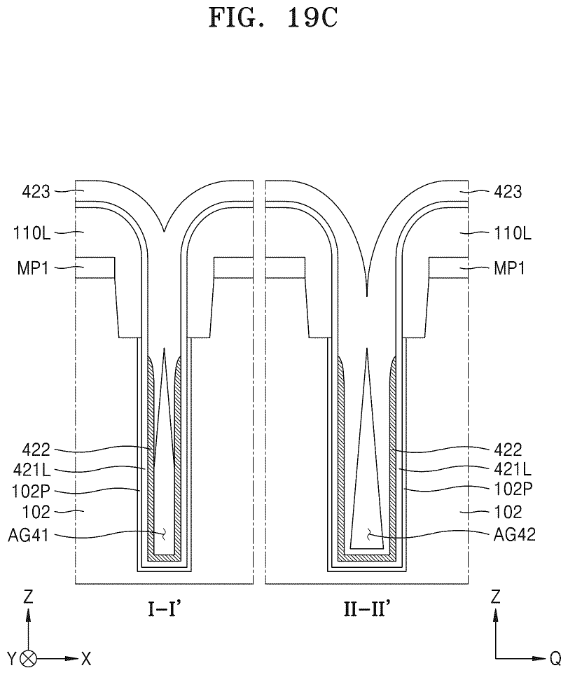

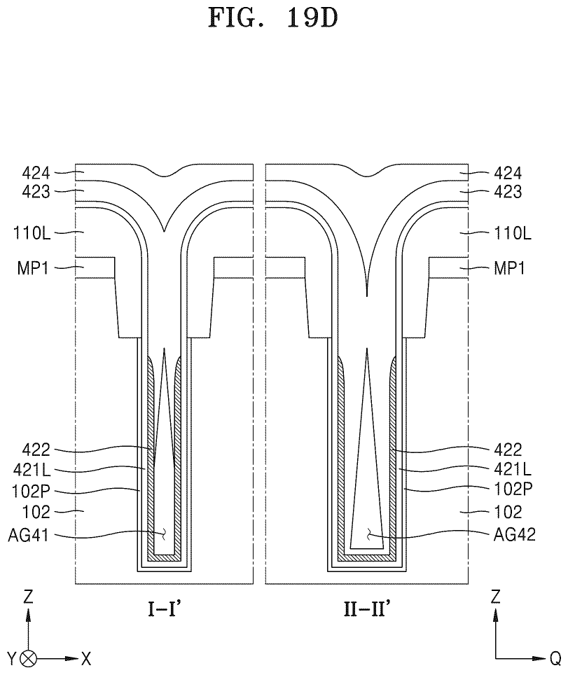

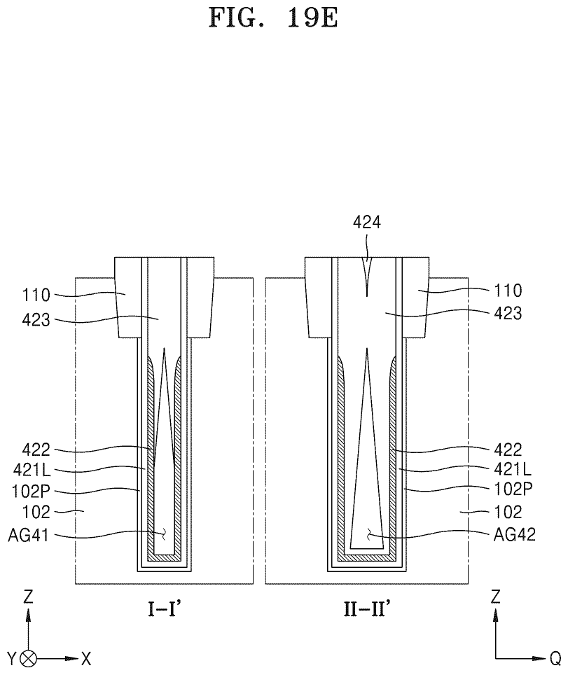

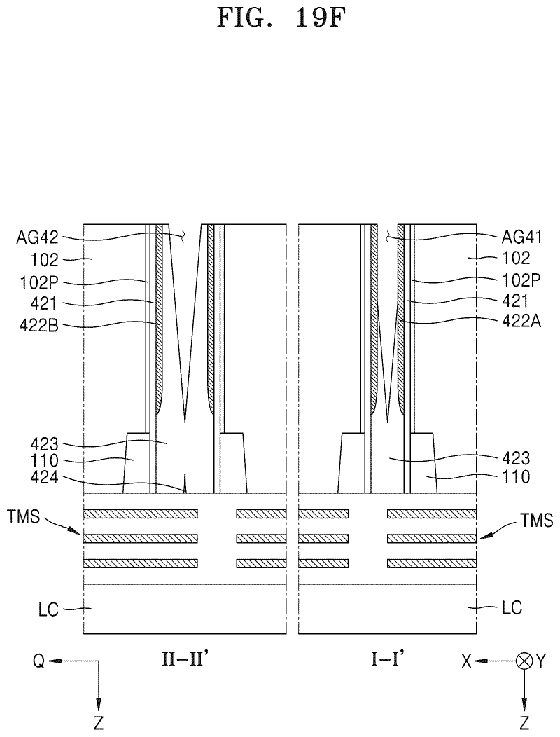

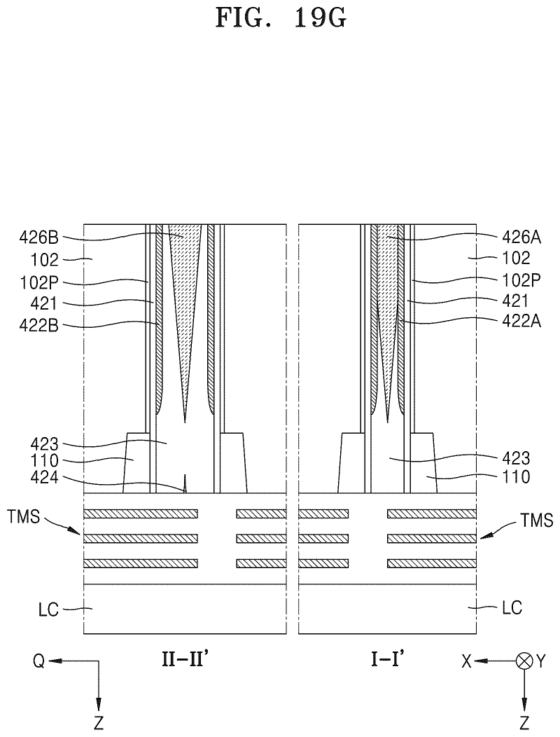

FIGS. 19A to 19G are cross-sectional views of a process sequence of a method of manufacturing an image sensor, according to embodiments. FIGS. 19A to 19G illustrate cross-sectional configurations of portions corresponding to cross-sections taken along lines I-I′ and II-II′ of FIG. 4, according to a process sequence. An example of a method of manufacturing the image sensor 400A shown in FIG. 11 is described with reference to FIGS. 19A to 19G. In FIGS. 19A to 19G, the same reference numerals are used to denote the same elements as in FIGS. 1 to 11, and detailed descriptions thereof are omitted for conciseness.

Referring to FIG. 19A, after the processes described with reference to FIGS. 16A to 16D are performed, a first insulating film 421L may be formed to conformally cover exposed surfaces in the resultant structure of FIG. 16D. In some embodiments, the first insulating film 421L may be formed by using an ALD process or a CVD process. The first insulating film 421L may be formed to a uniform thickness inside each of a portion of a deep trench T2A, which corresponds to a line isolation portion (refer to 420L in FIG. 11), and a portion of a deep trench T2B, which corresponds to a corner isolation portion (refer to 420C in FIG. 11).

Referring to FIG. 19B, a doped polysilicon liner 422 may be formed to conformally cover exposed surfaces in the resultant structure of FIG. 19A, and an upper portion of the doped polysilicon liner 422 may be removed by an etchback process, and thus, the doped polysilicon liner 422 may remain only inside the deep trenches T2A and T2B.

Referring to FIG. 19C, a second insulating pattern 423 may be formed on the resultant structure of FIG. 19B. The second insulating pattern 423 may be formed by using an ALD process, a CVD process, or a combination thereof.

During the formation of the second insulating pattern 423, a first air gap AG41 defined by the second insulating pattern 423 may be formed inside a portion of the deep trench T2A, which corresponds to the line isolation portion 420L, and a second air gap AG42 defined by the second insulating pattern 423 may be formed inside a portion of the deep trench T2B, which corresponds to the corner isolation portion 420C. The formation of the second insulating pattern 423, an entrance of each of the deep trenches T2A and T2B may be blocked by the second insulating pattern 423.

Referring to FIG. 19D, a third insulating pattern 424 may be formed on the resultant structure of FIG. 19C. The third insulating pattern 424 may be formed by using an ALD process, a CVD process, or a combination thereof. In some embodiments, after the third insulating pattern 424 is formed, an annealing process may be performed to densify the third insulating pattern 424.

Referring to FIG. 19E, processes similar to those described with reference to FIGS. 16H and 16I may be performed on the resultant structure of FIG. 19D to remove a mask pattern MP1 and expose a substrate 102.

Referring to FIG. 19F, processes similar to those described with reference to FIGS. 16J and 16K may be performed on the resultant structure of FIG. 19E to expose the first air gap AG41 and the second air gap AG42 to the outside.

Referring to FIG. 19G, processes similar to those described with reference to FIGS. 16L and 16M may be performed on the resultant structure of FIG. 19F to form a first metal pillar 426A filling the first air gap AG41 and a second metal pillar 426B filling the second air gap AG42. Thereafter, subsequent processes described with reference to FIG. 16M may be performed on the resultant structure of FIG. 19G, and thus, the image sensor 400A shown in FIG. 11 may be manufactured.

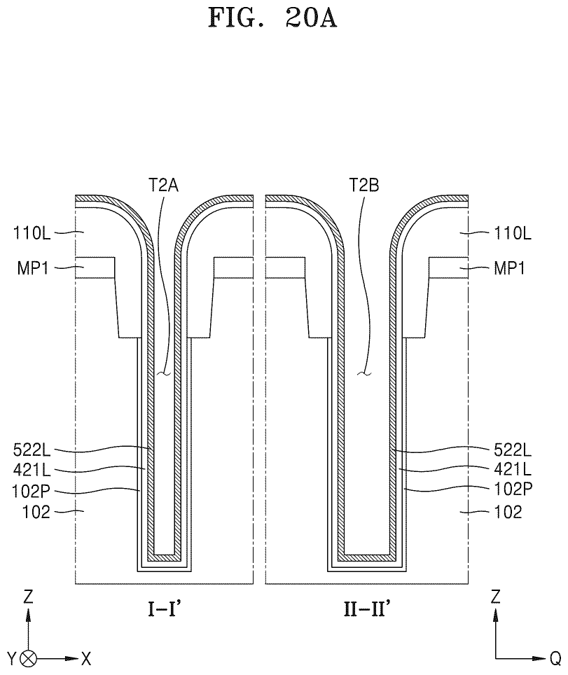

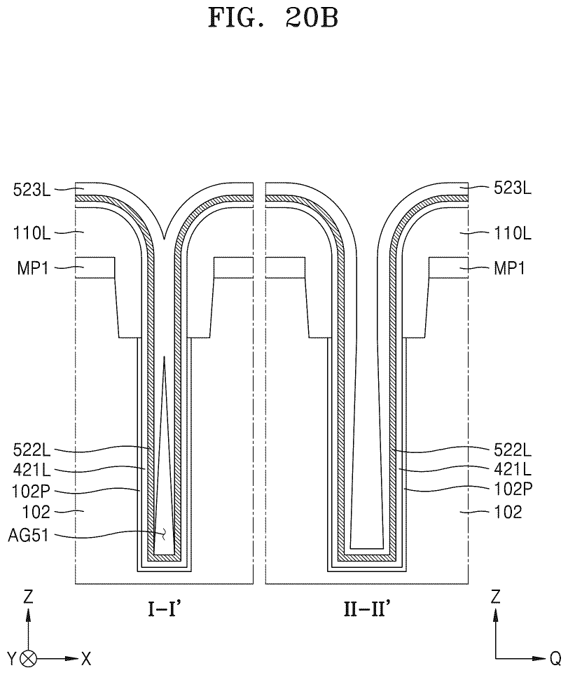

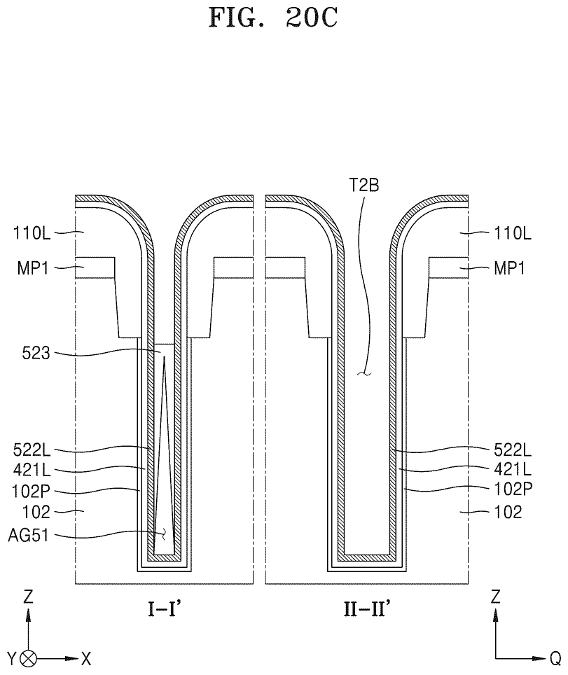

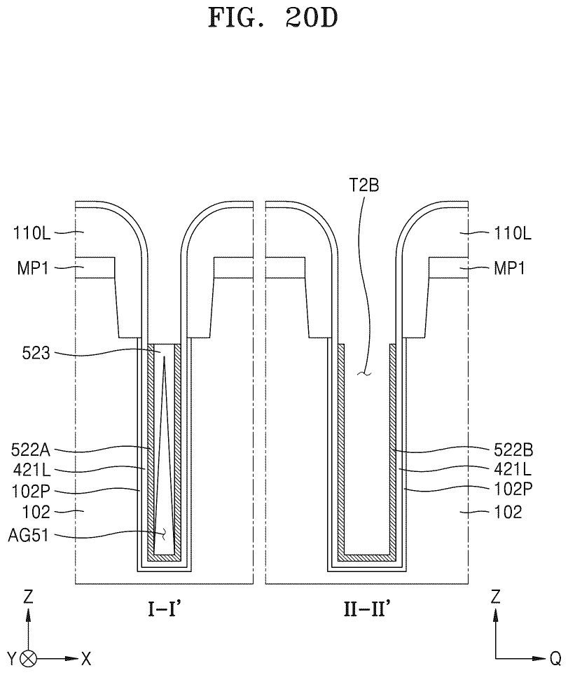

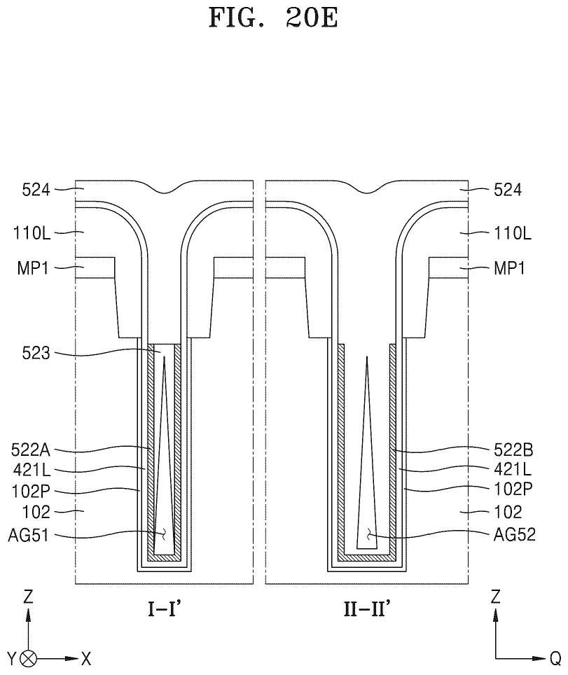

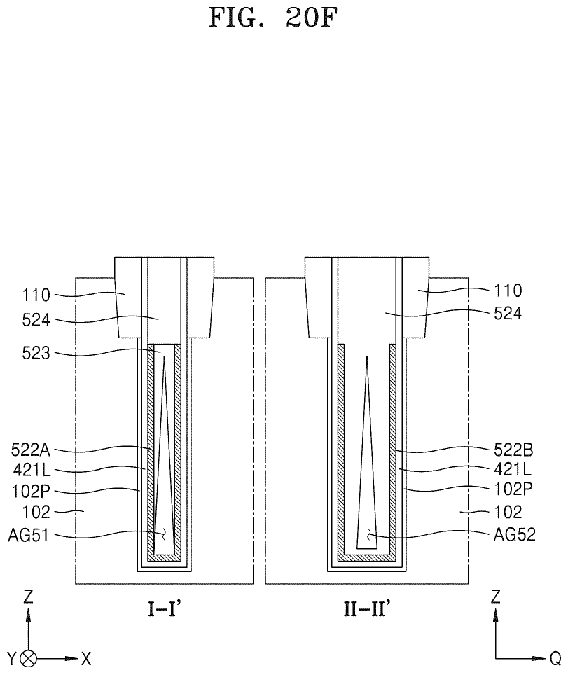

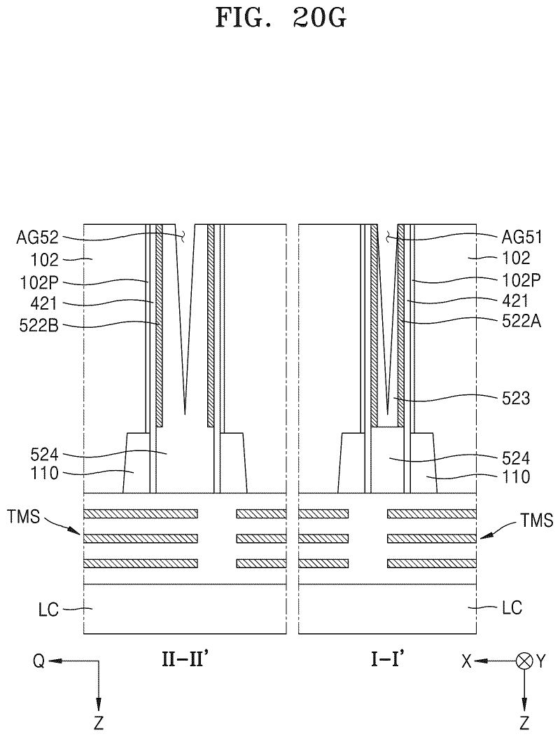

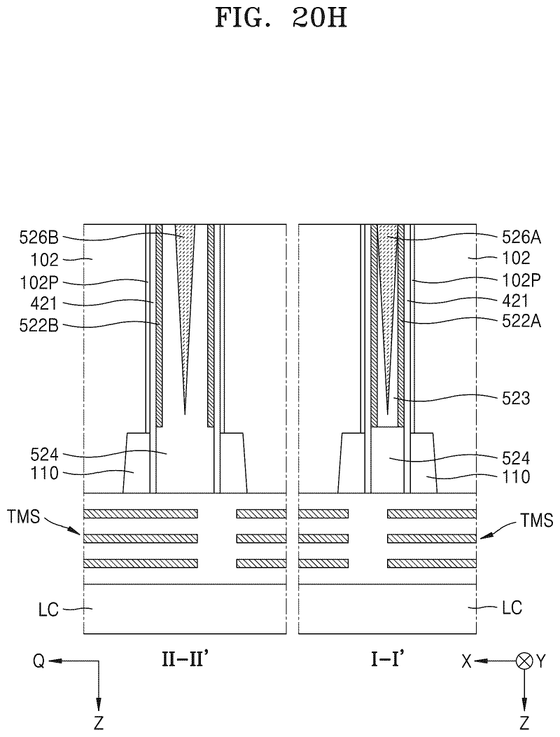

FIGS. 20A to 20H are cross-sectional views of a process sequence of a method of manufacturing an image sensor, according to embodiments. FIGS. 20A to 20H illustrate cross-sectional configurations of portions corresponding to cross-sections taken along lines I-I′ and II-II′ of FIG. 4, according to a process sequence. An example of a method of manufacturing the image sensor 500A shown in FIG. 14 is described with reference to FIGS. 20A to 20H. In FIGS. 20A to 20H, the same reference numerals are used to denote the same elements as in FIGS. 1 to 14, and detailed descriptions thereof are omitted for conciseness.

Referring to FIG. 20A, after the processes described with reference to FIGS. 16A to 16D are performed, a first insulating film 421L conformally covering exposed surfaces in the resultant structure of FIG. 16D may be formed in the same manner as that described with reference to FIG. 19A. Thereafter, a doped polysilicon liner 522L may be formed to conformally cover the first insulating film 421L.

Referring to FIG. 20B, a second insulating film 523L may be formed on the resultant structure of FIG. 20A. A constituent material of the second insulating film 523L may be the same as that of the second insulating pattern 523, which is described above. The second insulating film 523L may be formed by using an ALD process, a CVD process, or a combination thereof.

During the formation of the second insulating film 523L, it may be relatively difficult for source materials required to form the second insulating film 523L to reach the inside of a deep trench T2A because the inside of a portion of the deep trench T2A, which corresponds to the line isolation portion 120L, is narrower and deeper than the inside of a portion of a deep trench T2B, which corresponds to a corner isolation portion (refer to 520C in FIG. 14). Accordingly, a portion of the second insulating film 523L, which is formed inside the deep trench T2A, may have a smaller thickness than other portions of the second insulating film 523L, and an entrance of the deep trench T2A, which is a boundary between a shallow trench T1A and the deep trench T2A, may be blocked by the second insulating film 523L. As a result, a first air gap AG51 defined by the second insulating film 523L may be formed inside the deep trench T2A. During the formation of the second insulating film 523L, an entrance of a portion of the deep trench T2B, which corresponds to the corner isolation portion 520C, may remain connected to the outside.

Referring to FIG. 20C, an exposed portion of the second insulating film 523L may be removed from the resultant structure of FIG. 20B. Thus, the doped polysilicon liner 522L may be exposed in other partial regions except for the inside of the deep trench T2A, which is a relatively narrow and deep space. A portion of the second insulating film 523L, which defines the first air gap AG51, may be left as a second insulating pattern 523 inside the deep trench T2A.

Referring to FIG. 20D, an exposed upper portion of the doped polysilicon liner 524L may be partially removed from the resultant structure of FIG. 20C to expose an upper portion of the first insulating film 421L. As a result, a portion of the doped polysilicon liner 524L may remain as a first doped polysilicon pattern 522A inside the deep trench T2A, and another portion of the doped polysilicon liner 524L may remain as a second doped polysilicon pattern 522B inside the deep trench T2B.

Referring to FIG. 20E, a third insulating pattern 524 may be formed on the resultant structure of FIG. 20D. The third insulating pattern 524 may be formed by using an ALD process, a CVD process, or a combination thereof.

In some embodiments, because the deep trench T2A is blocked by the second insulating pattern 523 defining the first air gap AG51, the third insulating pattern 524 may be formed inside the deep trench T2B but may not be formed inside the deep trench T2A. During the formation of the third insulating pattern 524, a second air gap AG52 defined by the third insulating pattern 524 may be formed inside a portion of the deep trench T2B, which corresponds to the corner isolation portion 520C.

The third insulating pattern 524 may be formed by using an ALD process, a CVD process, or a combination thereof. In some embodiments, after the third insulating pattern 524 is formed, an annealing process may be performed to densify the third insulating pattern 524.

Referring to FIG. 20F, processes similar to those described with reference to FIGS. 16H and 16I may be performed on the resultant structure of FIG. 20E to remove the mask pattern MP1 and expose the substrate 102.

Referring to FIG. 20G, processes similar to those described with reference to FIGS. 16J and 16K may be performed on the resultant structure of FIG. 20F to expose the first air gap AG51 and the second air gap AG52 to the outside.

Referring to FIG. 20H, processes similar to those described with reference to FIGS. 16L and 16M may be performed on the resultant structure of FIG. 20G to form a first metal pillar 526A filling the first air gap AG51 and a second metal pillar 526B filling the second air gap AG52. Thereafter, subsequent processes described with reference to FIG. 16M may be performed on the resultant structure of FIG. 20H, and thus, the image sensor 500A shown in FIG. 14 may be manufactured.

Although the methods of manufacturing the image sensors 100A, 200, 300A, 400A, and 500A have been described with reference to FIGS. 16A to 20H, it will be understood that the image sensors having variously changed structures may be manufactured by applying various modifications and changes to the processes described with reference to FIGS. 16A to 20H within the scope of the present disclosure.

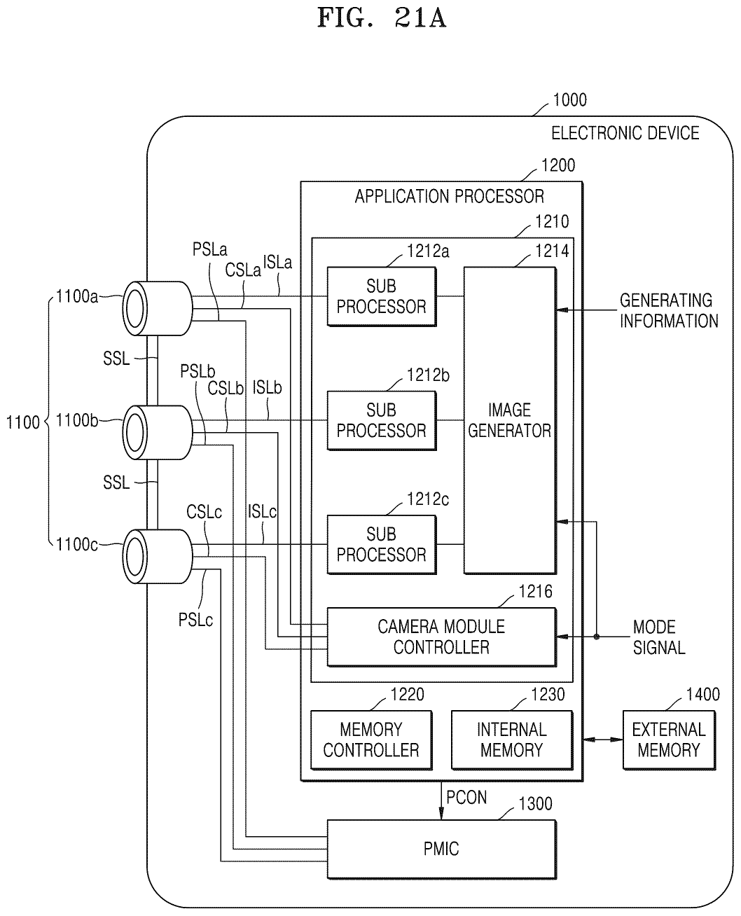

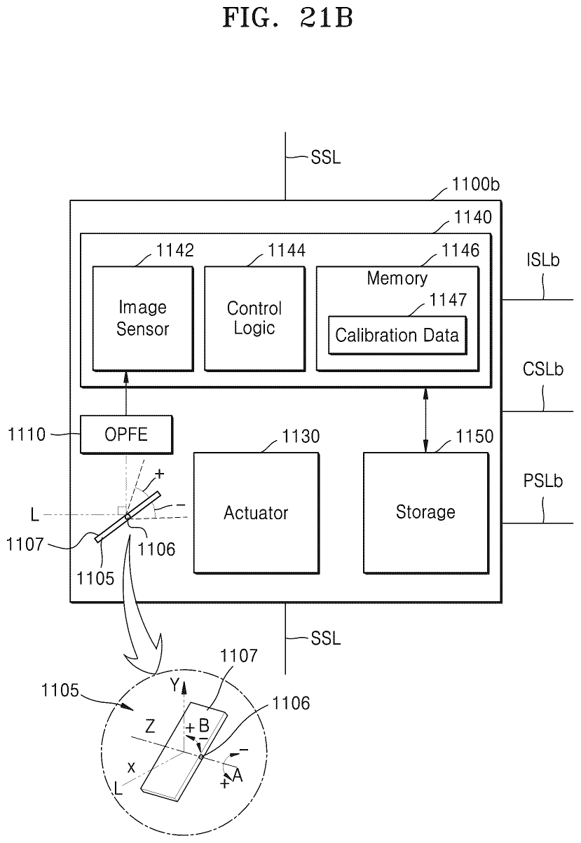

FIG. 21A is a block diagram of an electronic system 1000 according to embodiments, and FIG. 21B is a detailed block diagram of a camera module included in the electronic system of FIG. 21A.

Referring to FIG. 21A, the electronic system 1000 may include a camera module group 1100, an application processor 1200, a power management integrated circuit (PMIC) 1300, and an external memory 1400.

The camera module group 1100 may include a plurality of camera modules (e.g., 1100a, 1100b, and 1100c). Although three camera modules 1100a, 1100b, and 1100c are illustrated in FIG. 21A, embodiments are not limited thereto. In some embodiments, the camera module group 1100 may be modified to include only two camera modules. In some embodiments, the camera module group 1100 may be modified to include n camera modules, where n is a natural number of 4 or more.

The detailed configuration of the camera module 1100b will be described with reference to FIG. 21B below. The descriptions below may be also applied to the other camera modules 1100a and 1100c.

Referring to FIG. 21B, the camera module 1100b may include a prism 1105, an optical path folding element (OPFE) 1110, an actuator 1130, an image sensing device 1140, and a storage 1150.

The prism 1105 may include a reflective surface 1107 of a light reflecting material and may change the path of light L incident from the outside.

In some embodiments, the prism 1105 may change the path of the light L incident in a first direction (X direction in FIG. 21B) into a second direction (Y direction in FIG. 21B) that is perpendicular to the first direction. The prism 1105 may rotate the reflective surface 1107 of the light reflecting material in a direction A around a central shaft 1106 or rotate the central shaft 1106 in a direction B to change the path of the light L incident in the first direction (X direction) into the second direction (Y direction) perpendicular to the first direction (X direction). In this case, the OPFE 1110 may move in a third direction (Z direction in FIG. 21B), which is perpendicular to the first direction (X direction) and the second direction (Y direction).

In some embodiments, as shown in FIG. 21B, an A-direction maximum rotation angle of the prism 1105 may be less than or equal to about 15 degrees in a plus (+) A direction and greater than about 15 degrees in a minus (−) A direction, but embodiments are not limited thereto.

In some embodiments, the prism 1105 may move by an angle of about 20 degrees or in a range from about 10 degrees to about 20 degrees or from about 15 degrees to about 20 degrees in a plus or minus B direction. In this case, an angle by which the prism 1105 moves in the plus B direction may be the same as or similar, within a difference of about 1 degree, to an angle by which the prism 1105 moves in the minus B direction.

In some embodiments, the prism 1105 may move the reflective surface 1107 of the light reflecting material in the third direction (e.g., Z direction) parallel with an extension direction of the central shaft 1106.

The OPFE 1110 may include, for example, “m” optical lenses, where “m” is a natural number. The m lenses may move in the second direction (or Y direction) and change an optical zoom ratio of the camera module 1100b. For example, when the default optical zoom ratio of the camera module 1100b is Z, the optical zoom ratio of the camera module 1100b may be changed to 3Z or 5Z or greater by moving the m optical lenses included in the OPFE 1110.

The actuator 1130 may move the OPFE 1110 or an optical lens to a certain position. For example, the actuator 1130 may adjust the position of the optical lens such that an image sensor 1142 is positioned at a focal length of the optical lens for accurate sensing.

The image sensing device 1140 may include the image sensor 1142, a control logic 1144, and a memory 1146. The image sensor 1142 may sense an image of an object using the light L provided through the optical lens. The control logic 1144 may control all operations of the camera module 1100b. For example, the control logic 1144 may control operation of the camera module 1100b according to a control signal provided through a control signal line CSLb.

The memory 1146 may store information, such as calibration data 1147, for the operation of the camera module 1100b. The calibration data 1147 may include information, which is necessary for the camera module 1100b to generate image data using the light L provided from outside. The calibration data 1147 may include information about a degree of rotation, information about a focal length, information about an optical axis, or the like. When the camera module 1100b is implemented as a multi-state camera that has a focal length varying with the position of the optical lens, the calibration data 1147 may include a value of a focal length for each position (or state) of the optical lens and information about auto focusing.

The storage 1150 may store image data sensed by the image sensor 1142. The storage 1150 may be provided outside the image sensing device 1140 and may form a stack with a sensor chip of the image sensing device 1140. In some embodiments, the storage 1150 may be implemented as electrically erasable programmable read-only memory (EEPROM), but embodiments are not limited thereto.

The image sensor 1142 may include the image sensors 100, 100A, 100B, 200, 300A, 300B, 400A, 400B, 400C, 500A, 500B described with reference to FIGS. 1 to 15 or image sensors variously modified and changed therefrom within the scope of the present disclosure.

Referring to FIGS. 21A and 21B, in some embodiments, each of the camera modules 1100a, 1100b, and 1100c may include the actuator 1130. Accordingly, the camera modules 1100a, 1100b, and 1100c may include the calibration data 1147, which is the same or different among the camera modules 1100a, 1100b, and 1100c according to the operation of the actuator 1130 included in each of the camera modules 1100a, 1100b, and 1100c.

In some embodiments, one (e.g., the camera module 1100b) of the camera modules 1100a, 1100b, and 1100c may be of a folded-lens type including the prism 1105 and the OPFE 1110, which are described above, while the other camera modules (e.g., the camera modules 1100a and 1100c) may be of a vertical type that does not include the prism 1105 and the OPFE 1110. However, embodiments are not limited thereto.

In some embodiments, one (e.g., the camera module 1100c) of the camera modules 1100a, 1100b, and 1100c may include a vertical depth camera, which extracts depth information using an infrared ray (IR). In this case, the application processor 1200 may generate a three-dimensional (3D) depth image by merging image data provided from the depth camera with image data provided from another camera module (e.g., the camera module 1100a or 1100b).

In some embodiments, at least two camera modules (e.g., 1100a and 1100b) among the camera modules 1100a, 1100b, and 1100c may have different field-of-views. In this case, for example, the two camera modules (e.g., 1100a and 1100b) among the camera modules 1100a, 1100b, and 1100c may respectively have different optical lenses. However, embodiments are not limited thereto.

In some embodiments, the camera modules 1100a, 1100b, and 1100c may have different field-of-views from each other. In this case, although the camera modules 1100a, 1100b, and 1100c may respectively have different optical lenses, embodiments are not limited thereto.

In some embodiments, the camera modules 1100a, 1100b, and 1100c may be physically separated from one another. In other words, a sensing region of the image sensor 1142 is not divided and used by the camera modules 1100a, 1100b, and 1100c, but the image sensor 1142 may be independently included in each of the camera modules 1100a, 1100b, and 1100c.

Referring back to FIG. 21A, the application processor 1200 may include an image processing device 1210, a memory controller 1220, and an internal memory 1230. The application processor 1200 may be separately implemented from the camera modules 1100a, 1100b, and 1100c. For example, the application processor 1200 and the camera modules 1100a, 1100b, and 1100c may be implemented in different semiconductor chips and separated from each other.

The image processing device 1210 may include a plurality of sub-processors (e.g., 1212a, 1212b, and 1212c), an image generator 1214, and a camera module controller 1216. The image processing device 1210 may include sub-processors (e.g., 1212a, 1212b, and 1212c) in number corresponding to the number of camera modules (e.g., 1100a, 1100b, 1100c).

Pieces of image data respectively generated by the camera modules 1100a, 1100b, and 1100c may be respectively provided to the corresponding ones of the sub-processors 1212a, 1212b, and 1212c through image signal lines ISLa, ISLb, and ISLc separated from each other. For example, image data generated by the camera module 1100a may be provided to the sub-processor 1212a through the image signal line ISLa, image data generated by the camera module 1100b may be provided to the sub-processor 1212b through the image signal line ISLb, and image data generated by the camera module 1100c may be provided to the sub-processor 1212c through the image signal line ISLc. Such image data transmission may be performed using, for example, a mobile industry processor interface (MIPI)-based camera serial interface (CSI). However, embodiments are not limited thereto.

In some embodiments, a single sub-processor may be arranged to correspond to a plurality of camera modules. For example, differently from FIG. 14A, the sub-processors 1212a and 1212c may not be separated but may be integrated into a single sub-processor, and the image data provided from the camera module 1100a or the camera module 1100c may be selected by a selection element (e.g., a multiplexer) and then provided to the integrated sub-processor.

The image data provided to each of the sub-processors 1212a, 1212b, and 1212c may be provided to the image generator 1214. The image generator 1214 may generate an output image by using the image data provided from each of the sub-processors 1212a, 1212b, and 1212c according to image generation information or a mode signal.

Specifically, the image generator 1214 may generate the output image by merging at least portions of respective pieces of image data, which are respectively generated by the camera modules 1100a, 1100b, and 1100c having different field-of-views, according to the image generation information or the mode signal. in some embodiments, the image generator 1214 may generate the output image by selecting one of pieces of image data, which are respectively generated by the camera modules 1100a, 1100b, and 1100c having different field-of-views, according to the image generation information or the mode signal.

In some embodiments, the image generating information may include a zoom signal or a zoom factor. In some embodiments, the mode signal may be based on a mode selected by a user.

When the image generation information includes a zoom signal or a zoom factor and the camera modules 1100a, 1100b, and 1100c have different field-of-views, the image generator 1214 may perform different operations according to different kinds of zoom signals. For example, when the zoom signal is a first signal, the image generator 1214 may merge image data output from the camera module 1100a and image data output from the camera module 1100c and then generate an output image by using a merged image signal and image data output from the camera module 1100b and not used for merging. When the zoom signal is a second signal different from the first signal, the image generator 1214 may generate an output image by selecting one of the pieces of image data respectively output from the camera modules 1100a, 1100b, and 1100c, instead of performing the merging. However, embodiments are not limited thereto, and in some embodiments, a method of processing image data may be changed whenever necessary.

In some embodiments, the image generator 1214 may receive a plurality of pieces of image data, which have different exposure times, from at least one of the sub-processors 1212a, 1212b, and 1212c and perform high dynamic range (HDR) processing on the pieces of image data, thereby generating merged image data having an increased dynamic range.

The camera module controller 1216 may provide a control signal to each of the camera modules 1100a, 1100b, and 1100c. A control signal generated by the camera module controller 1216 may be provided to a corresponding one of the camera modules 1100a, 1100b, and 1100c through a corresponding one of control signal lines CSLa, CSLb, and CSLc, which are separated from one another.

One (e.g., the camera module 1100b) of the camera modules 1100a, 1100b, and 1100c may be designated as a master camera according to the mode signal or the image generation signal including a zoom signal, and the other camera modules (e.g., the camera modules 1100a and 1100c) may be designated as slave cameras. Such designation information may be included in a control signal and provided to each of the camera modules 1100a, 1100b, and 1100c through a corresponding one of the control signal lines CSLa, CSLb, and CSLc, which are separated from one another.

A camera module operating as a master or a slave may be changed according to a zoom factor or an operation mode signal. For example, when the field-of-view of the camera module 1100a is greater than that of the camera module 1100b and the zoom factor indicates a low zoom ratio, the camera module 1100b may operate as a master and the camera module 1100a may operate as a slave. In some embodiments, when the zoom factor indicates a high zoom ratio, the camera module 1100a may operate as a master and the camera module 1100b may operate as a slave.

In some embodiments, a control signal provided from the camera module controller 1216 to each of the camera modules 1100a, 1100b, and 1100c may include a sync enable signal. For example, when the camera module 1100b is a master camera and the camera modules 1100a and 1100c are slave cameras, the camera module controller 1216 may transmit the sync enable signal to the camera module 1100b. The camera module 1100b provided with the sync enable signal may generate a sync signal based on the sync enable signal and may provide the sync signal to the camera modules 1100a and 1100c through a sync signal line SSL. The camera modules 1100a, 1100b, and 1100c may be synchronized with the sync signal and may transmit image data to the application processor 1200.

In some embodiments, a control signal provided from the camera module controller 1216 to each of the camera modules 1100a, 1100b, and 1100c may include mode information according to the mode signal. The camera modules 1100a, 1100b, and 1100c may operate in a first operation mode or a second operation mode in relation with a sensing speed based on the mode information.

In the first operation mode, the camera modules 1100a, 1100b, and 1100c may generate an image signal at a first speed (e.g., at a first frame rate), encode the image signal at a second speed higher than the first speed (e.g., at a second frame rate higher than the first frame rate), and transmit an encoded image signal to the application processor 1200. In this case, the second speed may be 30 times or less the first speed.

The application processor 1200 may store the received image signal (i.e., the encoded image signal) in the internal memory 1230 therein or the external memory 1400 outside the application processor 1200. Thereafter, the application processor 1200 may read the encoded image signal from the internal memory 1230 or the external memory 1400, decode the encoded image signal, and display image data generated based on a decoded image signal. For example, a corresponding one of the sub-processors 1212a, 1212b, and 1212c of the image processing unit 1210 may perform the decoding and may also perform image processing on the decoded image signal.

In the second operation mode, the camera modules 1100a, 1100b, and 1100c may generate an image signal at a third speed lower than the first speed (e.g., at a third frame rate lower than the first frame rate) and transmit the image signal to the application processor 1200. The image signal provided to the application processor 1200 may not have been encoded. The application processor 1200 may perform image processing on the image signal or store the image signal in the internal memory 1230 or the external memory 1400.

The PMIC 1300 may provide power (e.g., a power supply voltage) to each of the camera modules 1100a, 1100b, and 1100c. For example, under control by the application processor 1200, the PMIC 1300 may provide first power to the camera module 1100a through a power signal line PSLa, second power to the camera module 1100b through a power signal line PSLb, and third power to the camera module 1100c through a power signal line PSLc.

The PMIC 1300 may generate power corresponding to each of the camera modules 1100a, 1100b, and 1100c and adjust the level of the power, in response to a power control signal PCON from the application processor 1200. The power control signal PCON may include a power adjustment signal for each operation mode of the camera modules 1100a, 1100b, and 1100c. For example, the operation mode may include a low-power mode. In this case, the power control signal PCON may include information about a camera module configured to operate in the low-power mode and a power level to be set. The same or different levels of power may be respectively provided to the camera modules 1100a, 1100b, and 1100c. The level of power may be dynamically changed.

While various embodiments have been particularly shown and described with reference to the drawings, it will be understood that various changes in form and details may be made therein without departing from the spirit and scope of the following claims.

What is claimed is:

1. An image sensor comprising:
a plurality of unit pixels arranged on a substrate; and
a pixel isolation structure passing through the substrate in a vertical direction, defining the plurality of unit pixels, and having a network-type planar structure,
wherein the pixel isolation structure comprises:
a line isolation portion and a corner isolation portion, the line isolation portion linearly extending along a side of each of two adjacent ones of the plurality of unit pixels between the two adjacent unit pixels, and the corner isolation portion contacting a corner of each of at least two adjacent ones of the plurality of unit pixels;
a conductive pillar comprising a first conductive pillar included in the line isolation portion and a second conductive pillar included in the corner isolation portion and integrally connected to the first conductive pillar; and
an insulating structure surrounding the conductive pillar in each of the line isolation portion and the corner isolation portion, the insulating structure comprising a first insulating structure included in the line isolation portion and a second insulating structure included in the corner isolation portion and integrally connected to the first insulating structure,
wherein the conductive pillar comprises a metal pillar included in at least one of the line isolation portion and the corner isolation portion, and a width of the metal pillar in a lateral direction is variable in the vertical direction.

2. The image sensor of claim 1, further comprising:
a wiring structure on a frontside surface of the substrate; and
a plurality of color filters and a plurality of microlenses on a backside surface of the substrate, the backside surface being opposite to the frontside surface of the substrate,
wherein, in the pixel isolation structure, the metal pillar has a tapered cross-sectional shape with the width in the lateral direction gradually increasing from the frontside surface of the substrate toward the backside surface thereof.

3. The image sensor of claim 1, further comprising:
a wiring structure on a frontside surface of the substrate; and
a plurality of color filters and a plurality of microlenses on a backside surface of the substrate, the backside surface being opposite to the frontside surface of the substrate,
wherein, in the pixel isolation structure, the insulating structure has a shape with a width in the lateral direction that gradually increases from the backside surface of the substrate toward the frontside surface of the substrate in each of the line isolation portion and the corner isolation portion.

4. The image sensor of claim 1, wherein the metal pillar is included in each of the line isolation portion and the corner isolation portion in the pixel isolation structure.

5. The image sensor of claim 1, wherein, in the pixel isolation structure, the metal pillar is included only in the line isolation portion, among the line isolation portion and the corner isolation portion.

6. The image sensor of claim 1, wherein:
the pixel isolation structure further comprises a doped polysilicon pattern included in at least one of the line isolation portion and the corner isolation portion, the doped polysilicon pattern being surrounded by the insulating structure, and
the doped polysilicon pattern is in contact with the metal pillar in at least one of the line isolation portion and the corner isolation portion.

7. The image sensor of claim 1, wherein the pixel isolation structure further comprises:
a local device isolation film that passes through only a portion of the substrate in the vertical direction and covers an outer sidewall of the insulating structure; and
a doped polysilicon pattern that is surrounded by the insulating structure in each of the line isolation portion and the corner isolation portion, the doped polysilicon pattern being spaced apart from the local device isolation film with the insulating structure therebetween,
wherein a width of the doped polysilicon pattern in the lateral direction increases away from the local device isolation film in the vertical direction.

8. The image sensor of claim 1, wherein each of the plurality of unit pixels comprises a photodiode formed in the substrate, and
the metal pillar comprises a metallic tapered surface which faces the photodiode and is inclined with respect to a backside surface of the substrate.

9. The image sensor of claim 1, wherein the metal pillar comprises a first metal pillar included in the line isolation portion and a second metal pillar included in the corner isolation portion and connected to the first metal pillar,
the insulating structure is in contact with the first metal pillar in the line isolation portion, and
the second insulating structure is in contact with the second metal pillar in the corner isolation portion.

10. The image sensor of claim 1, wherein the pixel isolation structure further comprises a first doped polysilicon pattern included in the line isolation portion and a second doped polysilicon pattern included in the corner isolation portion and connected to the first doped polysilicon pattern,
the metal pillar comprises a first metal pillar included in the line isolation portion and a second metal pillar included in the corner isolation portion and connected to the first metal pillar,
the first doped polysilicon pattern is in contact with the first metal pillar in the line isolation portion, and
the second doped polysilicon pattern is spaced apart from the second metal pillar in the corner isolation portion.

11. The image sensor of claim 1, wherein the pixel isolation structure further comprises a first doped polysilicon pattern included in the line isolation portion, a second doped polysilicon pattern included in the corner isolation portion and connected to the first doped polysilicon pattern, and an inner polysilicon pattern included in the corner isolation portion and surrounded by the second doped polysilicon pattern,
the metal pillar comprises a first metal pillar included in the line isolation portion and a second metal pillar included in the corner isolation portion and connected to the first metal pillar,
in the line isolation portion, the first doped polysilicon pattern is in contact with the first metal pillar, and
in the corner isolation portion, the inner polysilicon pattern is between the second metal pillar and the second doped polysilicon pattern and is in contact with each of the second metal pillar and the second doped polysilicon pattern.

12. The image sensor of claim 1, wherein the pixel isolation structure further comprises a first doped polysilicon pattern included in the line isolation portion, a second doped polysilicon pattern included in the corner isolation portion and connected to the first doped polysilicon pattern, and an inner polysilicon pattern included in the corner isolation portion and surrounded by the second doped polysilicon pattern,
the metal pillar is only in the line isolation portion, among the line isolation portion and the corner isolation portion,
the first doped polysilicon pattern is in contact with the metal pillar in the line isolation portion, and
the inner polysilicon pattern is at a center of the corner isolation portion.

13. The image sensor of claim 1, wherein the pixel isolation structure further comprises a first doped polysilicon pattern included in the line isolation portion and a second doped polysilicon pattern included in the corner isolation portion and connected to the first doped polysilicon pattern,
the metal pillar comprises a first metal pillar included in the line isolation portion and a second metal pillar included in the corner isolation portion and connected to the first metal pillar,
in the line isolation portion, a first portion of the first doped polysilicon pattern is in contact with the first metal pillar, and a second portion of the first doped polysilicon pattern is spaced apart from the first metal pillar, and
the second doped polysilicon pattern is spaced apart from the second metal pillar in the corner isolation portion.

14. The image sensor of claim 1, wherein the pixel isolation structure further comprises a first doped polysilicon pattern included in the line isolation portion, a second doped polysilicon pattern included in the corner isolation portion and connected to the first doped polysilicon pattern, and an inner polysilicon pattern included in the corner isolation portion and surrounded by the second doped polysilicon pattern,
the metal pillar is only in the line isolation portion, among the line isolation portion and the corner isolation portion,
in the line isolation portion, a first portion of the first doped polysilicon pattern is in contact with the metal pillar, and a second portion of the first doped polysilicon pattern is spaced apart from the metal pillar, and
the inner polysilicon pattern is at a center of the corner isolation portion.

15. The image sensor of claim 1, wherein, in each of the line isolation portion and the corner isolation portion, the insulating structure has a multilayered structure comprising a plurality of insulating films with thicknesses in the lateral direction different from each other.

16. An image sensor comprising:
a plurality of unit pixels respectively comprising a plurality of photodiodes arranged in a substrate having a frontside surface and a backside surface, the plurality of unit pixels having a two-dimensional array structure arranged in a matrix form along a plurality of row lines and a plurality of column lines; and
a pixel isolation structure comprising a main device isolation film and a local device isolation film, the main device isolation film passing through the substrate from the frontside surface of the substrate to the backside surface of the substrate and defining the plurality of unit pixels, the local device isolation film passing through only a portion of the substrate from the frontside surface of the substrate in a vertical direction, and covering a partial sidewall of the main device isolation film which is adjacent to the frontside surface of the substrate,
wherein the pixel isolation structure comprises:
a line isolation portion and a corner isolation portion, the line isolation portion linearly extending along a side of each of two adjacent ones of the plurality of unit pixels between the two adjacent unit pixels, and the corner isolation portion being in contact with a corner of each of at least two adjacent ones of the plurality of unit pixels;
a conductive pillar comprising a first conductive pillar included in the line isolation portion and a second conductive pillar included in the corner isolation portion and integrally connected to the first conductive pillar; and
an insulating structure surrounding the conductive pillar in each of the line isolation portion and the corner isolation portion, the insulating structure comprising a first insulating structure included in the line isolation portion and a second insulating structure included in the corner isolation portion and integrally connected to the first insulating structure,
wherein the conductive pillar comprises a metal pillar included in at least one of the line isolation portion and the corner isolation portion, and a width of the metal pillar in a lateral direction is variable in the vertical direction.

17. The image sensor of claim 16, wherein, in the pixel isolation structure, the metal pillar has a tapered cross-sectional shape with the width in the lateral direction gradually increasing from the frontside surface of the substrate toward the backside surface of the substrate.

18. The image sensor of claim 16, wherein, in the pixel isolation structure, the insulating structure has a shape with a width in the lateral direction that gradually increases from the backside surface of the substrate toward the frontside surface of the substrate in each of the line isolation portion and the corner isolation portion.

19. The image sensor of claim 16, wherein the pixel isolation structure further comprises a doped polysilicon pattern included in at least one of the line isolation portion and the corner isolation portion, the doped polysilicon pattern being surrounded by the insulating structure, and
the doped polysilicon pattern is in contact with the metal pillar in at least one of the line isolation portion and the corner isolation portion.

20. An electronic system comprising:
at least one camera module comprising an image sensor; and
a processor configured to process image data provided by the at least one camera module,
wherein the image sensor comprises:
a plurality of unit pixels arranged on a substrate; and
a pixel isolation structure passing through the substrate in a vertical direction, defining the plurality of unit pixels, and having a network-type planar structure,
wherein the pixel isolation structure comprises:
a line isolation portion and a corner isolation portion, the line isolation portion linearly extending along a side of each of two adjacent ones of the plurality of unit pixels between the two adjacent unit pixels, the corner isolation portion being in contact with a corner of each of at least two adjacent ones of the plurality of unit pixels;
a conductive pillar comprising a first conductive pillar included in the line isolation portion and a second conductive pillar included in the corner isolation portion and integrally connected to the first conductive pillar; and
an insulating structure surrounding the conductive pillar in each of the line isolation portion and the corner isolation portion, the insulating structure comprising a first insulating structure included in the line isolation portion and a second insulating structure included in the corner isolation portion and integrally connected to the first insulating structure,
wherein the conductive pillar further comprises a metal pillar included in at least one of the line isolation portion and the corner isolation portion, and a width of the metal pillar in a lateral direction is variable in the vertical direction.
